(19) United States
(12) Patent Application Publication
(10) Pub. No.: US 2025/0323123 A1
(43) Pub. Date: Oct. 16, 2025

(54) COOLER AND SEMICONDUCTOR MODULE

(71) Applicant: FUJI ELECTRIC CO., LTD., Kawasaki-shi (JP)

(72) Inventor: Takanori TANAKA, Kawasaki-shi (JP)

(73) Assignee: FUJI ELECTRIC CO., LTD., Kawasaki-shi (JP)

(21) Appl. No.: 19/069,620

(22) Filed: Mar. 4, 2025

(30) Foreign Application Priority Data
Apr. 11, 2024 (JP) 2024-063947

(51) Int. Cl. H01L 23/473; H01L 23/367; H05K 1/02

(52) U.S. Cl. CPC H01L 23/473; H01L 23/3672; H05K 1/0203

(57) ABSTRACT

A cooler having a flow path, including a first section and a second section downstream to the first section, for a refrigerant. The cooler includes: a top plate having a first surface and a second surface opposite to each other; a bottom plate having a first surface and a second surface opposite to each other, the second surface facing the first surface of the top plate; a plurality of fins arranged between the first surface of the top plate and the second surface of the bottom plate; and a frame provided between the top plate and the bottom plate, and having a wall surface surrounding the plurality of fins. An arrangement density of the fins is the same in the first and second sections. A contact area between each of the fins and the top plate in the first section is smaller than that in the second section.

### CROSS-REFERENCE TO RELATED APPLICATIONS

This application is based upon and claims the benefit of priority to Japanese Patent Application No. 2024-063947, filed on Apr. 11, 2024, the entire contents of which are incorporated herein by reference.

### BACKGROUND OF THE INVENTION

### 1. TECHNICAL FIELD

The present invention relates to a cooler and a semiconductor module.

### 2. DESCRIPTION OF THE RELATED ART

Some coolers that cool electronic components such as semiconductor devices include a plurality of fins arranged in a flow path of a refrigerant through which a refrigerant flows. In some coolers of this type, the density of the fins is gradually increased from an inlet to an outlet in order to suppress a decrease in cooling efficiency from the inlet to the outlet in the refrigerant flow path (for example, JP 2010-153785 A).

### SUMMARY OF THE INVENTION

In the cooler described above, since the temperature of the refrigerant gradually increases from the inlet toward the outlet, it is difficult to equalize the temperature of a heating element at a position close to the inlet and the temperature of the heating element at a position close to the outlet.

The present invention has been made in view of such a point, and an object of the present invention is to make the temperature of the heating element uniform along a flowing direction of the refrigerant.

A cooler according to one aspect of the present invention includes a top plate portion having a first surface facing a flow path of a refrigerant and having a heating element disposed on a back surface of the first surface; a bottom plate portion having a second surface facing the first surface of the top plate portion; a plurality of fins arranged between the first surface of the top plate portion and the second surface of the bottom plate portion; and a frame portion provided between the top plate portion and the bottom plate portion and having a wall surface surrounding the plurality of fins. The plurality of fins are arranged between the first face of the top plate portion and the second surface of the bottom plate portion such that an arrangement density of fins in a first section of the flow path of the refrigerant is equal to an arrangement density of fins in a second section downstream of the first section, and a contact area between the fin and the top plate portion in the first section is smaller than a contact area between the fin and the top plate portion in the second section.

According to the present invention, the temperature of the heating element along the flowing direction of the refrigerant can be made uniform.

### BRIEF DESCRIPTION OF THE DRAWINGS

FIG. 1 is a plan view of a cooler according to a first embodiment;

FIG. 2 is a plan view illustrating a flow path of a refrigerant;

FIG. 3A is a perspective view and FIG. 3B is a sectional view for explaining a configuration example of a corrugated fin;

FIG. 4 is a circuit diagram illustrating a circuit configuration example of a semiconductor module including a heating element;

FIG. 5 is a sectional view illustrating a wave shape of the corrugated fin in a first heat exchange section of an upstream portion;

FIG. 6 is a sectional view illustrating a wave shape of the corrugated fin in a second heat exchange section of a midstream portion;

FIG. 7 is a sectional view illustrating a wave shape of a corrugated fin in a third heat exchange section in a downstream portion;

FIG. 8 is a side sectional view illustrating a first contact state between a lower surface of a top plate and an upper bent portion of a corrugated fin;

FIG. 9 is a side sectional view illustrating a second contact state between the lower surface of the top plate and the upper bent portion of the corrugated fin;

FIG. 10 is a side sectional view illustrating a third contact state between the lower surface of the top plate and the upper bent portion of the corrugated fin;

FIG. 11 is a graph illustrating a relationship between a shape of the corrugated fin and a temperature of a semiconductor element;

FIG. 12 is a graph illustrating a relationship between presence or absence of a heat insulating region and the temperature of the semiconductor element;

FIG. 13 is a plan view of a cooler according to a second embodiment;

FIG. 14 is a side sectional view illustrating a wave shape of the corrugated fin and a shape of a lower surface of the top plate;

FIG. 15 is a side sectional view illustrating a second contact state between the lower surface of the top plate and the upper bent portion of the corrugated fin;

FIG. 16 is a side sectional view illustrating the wave shape of the corrugated fin and the shape of the lower surface of the top plate in the cooler according to a third embodiment;

FIG. 17 is a side sectional view illustrating a second contact state between the lower surface of the top plate and the upper bent portion of the corrugated fin;

FIG. 18 is a side sectional view illustrating a wave shape of the corrugated fin and a shape of the lower surface of the top plate in the cooler according to a fourth embodiment;

FIGS. 19A and 19B are side sectional views illustrating a contact state between the lower surface of the top plate and the upper bent portion of the corrugated fin in the first heat exchange section of an upstream portion;

FIG. 20 is a side sectional view illustrating a contact state between the lower surface of the top plate and the upper bent portion of the corrugated fin in the second heat exchange section of the midstream portion;

FIG. 21 is a side sectional view illustrating a contact state between the lower surface of the top plate and the upper bent portion of the corrugated fin in the third heat exchange section in the downstream portion; and

FIGS. 22A to 22C are sectional views illustrating fins of a cooler according to a fifth embodiment.

### DETAILED DESCRIPTION

Hereinafter, embodiments of the present invention will be described in detail with reference to the drawings. Note that an X axis, a Y axis, and a Z axis in each of the drawings to be referred to are illustrated for the purpose of defining a plane and a direction in the exemplified cooler or the like. The X, Y, and Z axes are orthogonal to each other and form a right-handed system. In the following description, a direction parallel to the X axis is referred to as an X direction, a direction parallel to the Y axis is referred to as a Y direction, and a direction parallel to the Z axis is referred to as a Z direction. Also, in a case where each of the X direction, the Y direction, and the Z direction is associated with a direction of an arrow (positive or negative) of a corresponding one of the X axis, the Y axis, and the Z axis illustrated, a “positive side” or a “negative side” is added.

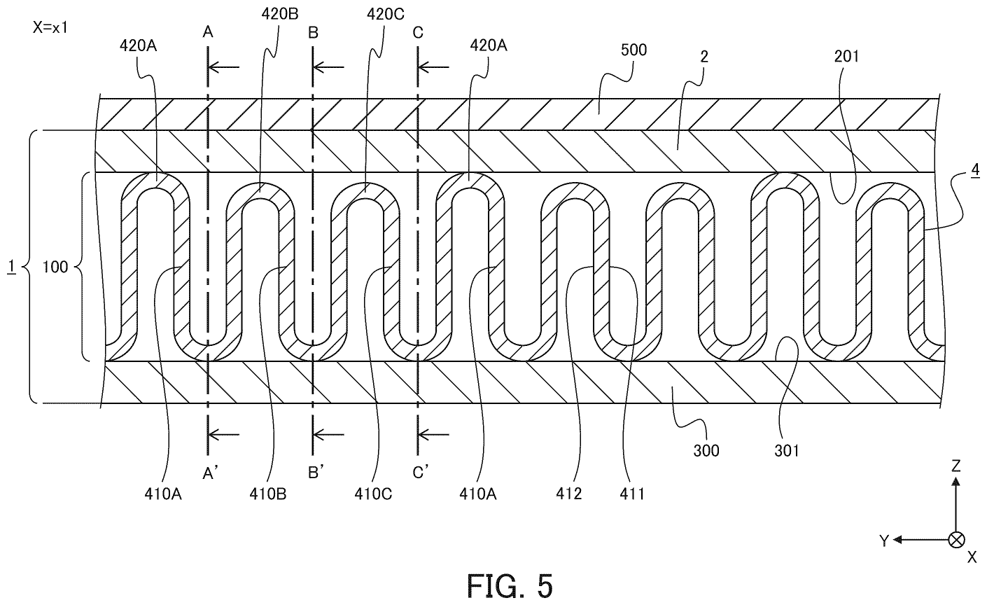

In the present specification, the Z direction may be referred to as a vertical direction. In the present specification, “on” and “upper side” are intended to be on the positive side in the Z direction with respect to the reference surface, member, position, and the like, and “below” and “lower side” are intended to be on the negative side in the Z direction with respect to the reference surface, member, position, and the like. For example, when it is described that “the member B is disposed on the member A”, the member B is disposed on the positive side in the Z direction as viewed from the member A. Further, when the “upper surface of the member A” is described, the surface is positioned at the end of the member A on the positive side in the Z direction and faces the positive side in the Z direction. Such directions and surfaces are terms used for convenience of description. Thus, depending on a posture of attachment of the cooler, a correspondence relationship with directions of the X, Y, and Z axes may vary. For example, a surface of the cooler on which the wiring board and the semiconductor element are arranged is referred to as an upper surface of the cooler in the present specification, but is not limited thereto, and may be referred to as a lower surface, a side surface, or the like of the cooler. In addition, the vertical direction and the horizontal direction when the diagram of a printed sheet is a diagram obtained by rotating an actual object counterclockwise by 90 degrees (for example, FIG. 5 and the like) are directions obtained by rotating the vertical direction and the horizontal direction on the printed sheet by 90 degrees in a half-time counting direction. For example, “the left side of the drawing” and “the right side of the drawing” in FIG. 5 respectively refer to “the lower side of the drawing” and “the upper side of the drawing” in the printed sheet.

An aspect ratio and a size relationship between the members in each drawing are merely schematically represented, and do not necessarily coincide with a relationship in a cooler or the like actually manufactured. For convenience of description, it is also assumed that the size relationship between the respective members is exaggerated. Among the symbols in the drawings, an underlined symbol indicates that the symbol refers to the entire component when a part of the component referred to by the symbol is referred to by another symbol. The alphabet in the symbols in the drawings and the alphabet following the numerals is intended only to distinguish a plurality of components specified by the numeral portion. In the following description, when a plurality of components are not distinguished by an alphabet following a numeral, the alphabet is omitted. For example, when referring to a specific heating element among the three heating elements 5A to 5C, the symbols are described up to alphabets, and in other cases, the heating element is simply described as a “heating element 5”. In addition, the description of “first”, “second”, and the like in the following description is only intended to distinguish a plurality of components having the same name.

In addition, in the following description, detailed descriptions of the configuration, function, operation, manufacturing method, and the like of the illustrated cooler that are the same as or similar to those of known coolers will be omitted.

### First Embodiment

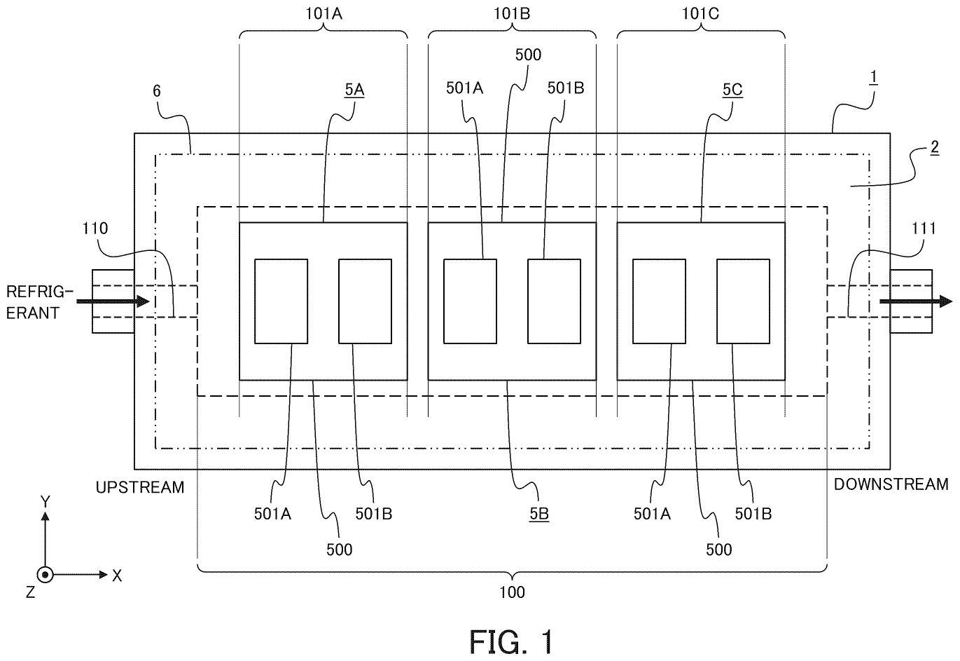

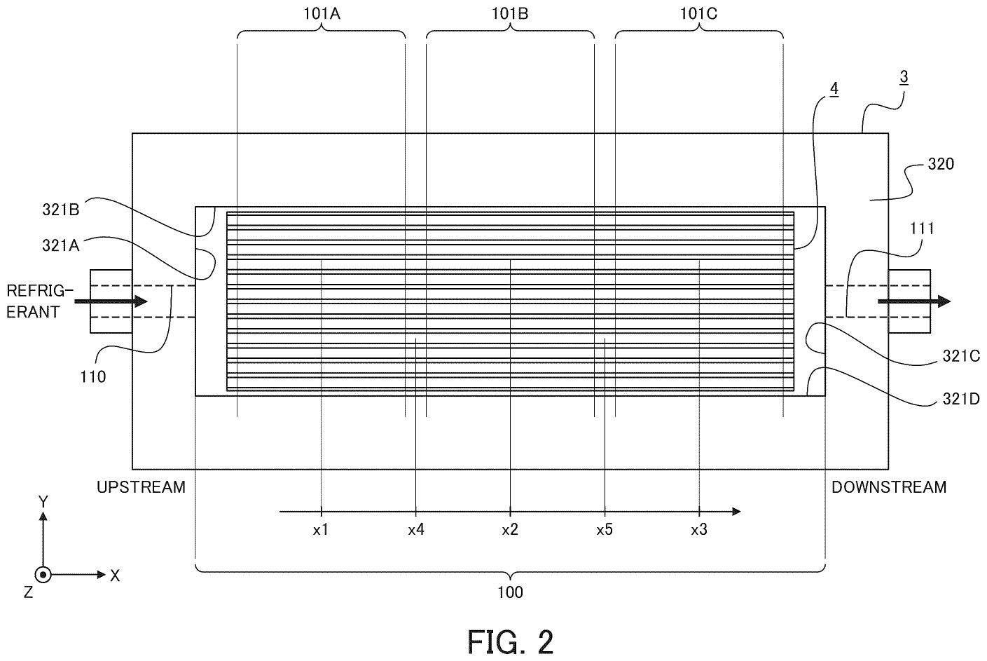

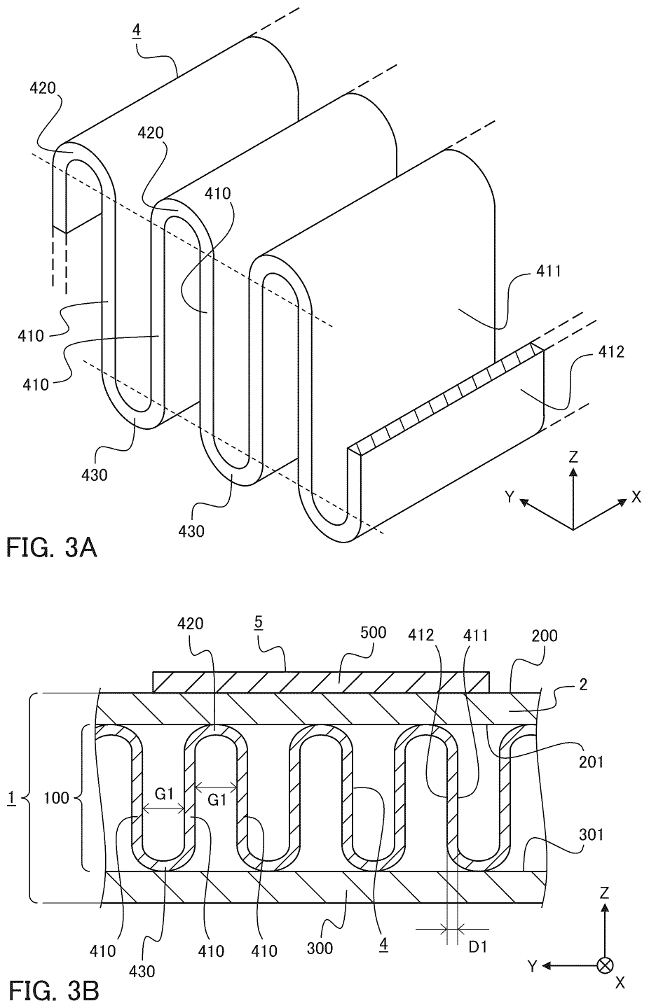

FIG. 1 is a plan view of a cooler according to a first embodiment. FIG. 2 is a plan view illustrating a flow path of a refrigerant. FIG. 3 is a perspective view (FIG. 3A) and a sectional view (FIG. 3B) for explaining a configuration example of the corrugated fin. FIG. 2 may be a view in which a top plate 2 in which a heating element 5 is disposed in the cooler 1 of FIG. 1 is omitted. The sectional view of FIG. 3B may be a sectional view parallel to a YZ plane at a position x3 in an X direction illustrated in FIG. 2.

The cooler 1 illustrated in FIGS. 1 to 3 includes the top plate 2, a water jacket 3, and a corrugated fin 4. The top plate 2 and the water jacket 3 are made of a metal or alloy having high thermal conductivity such as aluminum or copper, and are manufactured by a known method such as casting, pressing, or a method using a 3D printer. The corrugated fin 4 is formed by bending a metal plate made of aluminum, copper, stainless steel, or the like into a wave shape, and is disposed in a flow path 100 of the refrigerant defined by the top plate 2 and the water jacket 3. The top plate 2 may be referred to as a top plate portion.

In the top plate 2, the heating element 5 is disposed on an upper surface 200 which is an outer surface (may be referred to as an outer surface) of the cooler 1. The illustrated top plate 2 is a plate-shaped member having a rectangular shape in a plan view (XY plan view) of the upper surface 200, and three heating elements 5A to 5C are arranged along the longitudinal direction (X direction). The heating element 5 may be, for example, a circuit component including a wiring board 500 and a semiconductor element (semiconductor chip) 501 disposed on the upper surface of the wiring board 500. The wiring board 500 may be a stacked substrate in which conductive plates (may be referred to as a conductive pattern, a conductive layer, a conductor layer, or the like) made of copper or the like are arranged on upper and lower surfaces of an insulating substrate made of ceramics, an insulating resin, or the like, and the conductive plate disposed on the lower surface of the insulating substrate is bonded to the upper surface 200 of the top plate 2 via a bonding material such as solder. The number of the heating elements 5 disposed on the upper surface 200 of the top plate 2 is not limited to three. The heating element 5 is not limited to one in which two semiconductor elements 501A and 501B are arranged along the longitudinal direction of the upper surface 200 of the top plate 2 as illustrated in FIG. 1. A plurality of the heating elements 5 having different configurations may be disposed on the upper surface 200 of the top plate 2 via a bonding material such as solder. A case 6 having a frame-shaped portion surrounding the heating element 5 in a plan view may be disposed on the upper surface 200 of the top plate 2. The case 6 may include an insulating resin portion having a frame-shaped portion surrounding the heating element 5 in a plan view, and a terminal electrically connected to a wiring (conductive plate) of the wiring board 500 or an electrode of the semiconductor element 501 in the heating element 5. The heating element 5 and the like in a space surrounded by the case 6 may be sealed with an epoxy resin or the like. The heating element 5 may be a part of a resin-sealed semiconductor device (semiconductor package) such as a dual inline package (DIP) type. In this specification, an aggregate of one wiring board 500 and the semiconductor elements 501 arranged on the wiring board 500 is referred to as a heating element 5, but each semiconductor element 501 may be referred to as a heating element.

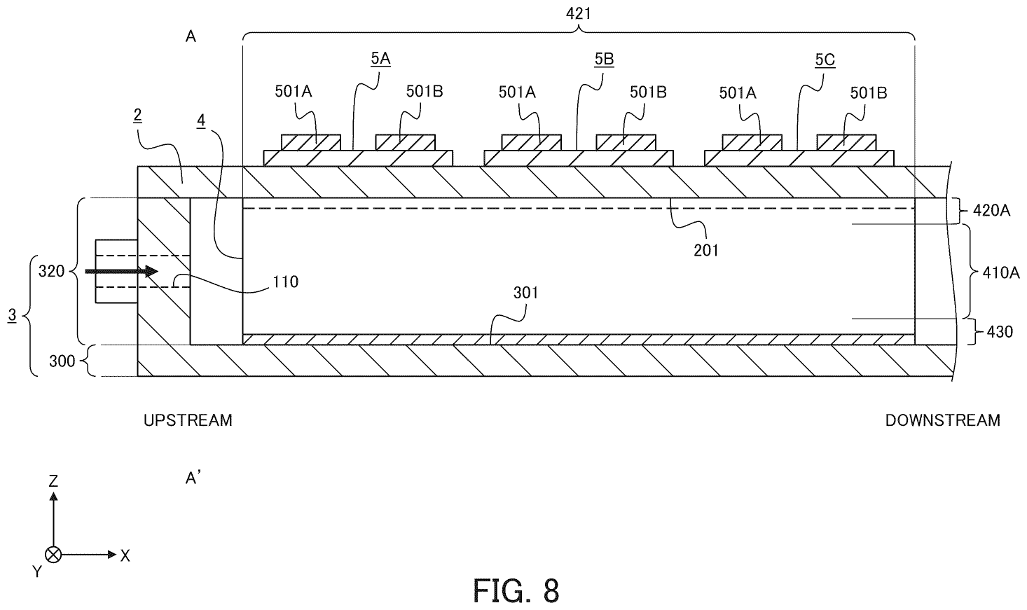

The water jacket 3 is a member that is attached to the lower surface 201 of the top plate 2 to form the flow path 100 of the refrigerant, and includes a bottom plate portion 300 and a frame portion 320 (refer to FIG. 8 and the like for a specific configuration). In the illustrated water jacket 3, the bottom plate portion 300 is a plate-shaped portion having a rectangular shape in a plan view (XY plan view) of the upper surface 301 facing the lower surface 201 of the top plate 2. The frame portion 320 is a portion positioned above the bottom plate portion 300 and having a square annular shape in the XY plan view. The frame portion 320 may be integrally formed with the bottom plate portion 300, or may be formed separately from the bottom plate portion 300. The bottom plate portion 300 and the frame portion 320 formed separately may be bonded by a bonding material, by laser welding or ultrasonic bonding, or may be fastened by a bolt or the like. Although FIG. 1 illustrates the cooler 1 in which a contour of the top plate 2 matches a contour of the water jacket 3, the contour of the top plate 2 may not match the contour of the water jacket 3. The top plate 2 may have any shape as long as it can close (cover) an opening at an upper end of the frame portion 320 of the water jacket 3. The frame portion 320 of the cooler 1 may be integrally formed with the top plate 2.

The flow path 100 of the refrigerant of the cooler 1 can be a substantially rectangular parallelepiped space defined by the upper surface 301 of the bottom plate portion 300, the lower surface 201 of the top plate 2, and inner peripheral wall surfaces 321A to 321D of the frame portion 320 connected to the upper surface 301 of the bottom plate portion 300 and the lower surface 201 of the top plate 2. The flow path 100 of the refrigerant communicates with the outside of the cooler 1 through a first through hole 110 formed in the frame portion 320 so as to have one opening end in the first inner peripheral wall surface 321A positioned at one end in the longitudinal direction and a second through hole 111 formed in the frame portion 320 so as to have one opening end in the second inner peripheral wall surface 321C positioned at the other end in the longitudinal direction (refer to FIG. 2 and the like). In the present specification, the first through hole 110 is used as an inlet of the refrigerant to the flow path 100 of the refrigerant, and the second through hole 111 is used as an outlet of the refrigerant from the flow path 100 of the refrigerant. That is, the cooler 1 exemplified is connected to a cooling circuit that circulates the refrigerant such that the refrigerant in the flow path 100 of the refrigerant flows toward the positive side in the X direction. In the following description, the first through hole 110 is referred to as an inlet 110 of the refrigerant, and the second through hole 111 is referred to as an outlet 111 of the refrigerant. In the following description, the X direction, the Y direction, and the Z direction in the flow path 100 of the refrigerant are referred to as a flowing direction, a flow path width direction, and a flow path height direction of the refrigerant, respectively.

As described above, the corrugated fin 4 formed by bending a metal plate into a wave shape is disposed in the flow path 100 of the refrigerant defined by the top plate 2 and the water jacket 3. The corrugated fin 4 is disposed in the flow path 100 of the refrigerant in a direction in which the traveling direction of the waveform is the flow path width direction (Y direction) and the amplitude direction of the waveform is the flow path height direction (Z direction). As illustrated in FIGS. 3A and 3B, the corrugated fin 4 disposed in the flow path 100 of the refrigerant includes a plurality of plate-shaped portions 410 arranged in the flow path width direction, and a plurality of upper bent portions 420 and a plurality of lower bent portions 430 connecting the plate-shaped portions 410 adjacent to each other in the flow path width direction. The upper bent portion 420 is a bent portion that connects the plate-shaped portions 410 adjacent to each other between the plate-shaped portion 410 and the top plate 2, and the lower bent portion 430 is a bent portion that connects the plate-shaped portions 410 adjacent to each other between the plate-shaped portion 410 and the bottom plate portion 300. The adjacent plate-shaped portions 410 are connected by one of the upper bent portion 420 and the lower bent portion 430.

In the plate-shaped portion 410, end surfaces 411 and 412 in the direction of a plate thickness D1 (hereinafter, referred to as “plate thickness direction”) are used for heat exchange with the refrigerant. In the following description, the end surfaces 411 and 412 in the plate thickness direction of the plate-shaped portion 410 are referred to as heat exchange surfaces 411 and 412, respectively. Each plate-shaped portion 410 of the corrugated fin 4 is disposed in parallel with the flowing direction (X direction) of the refrigerant, and extends in the flowing direction of the refrigerant such that one end of the heat exchange surfaces 411 and 412 in the flowing direction of the refrigerant is positioned on the upstream side (inlet 110 side of the refrigerant) of the first heat exchange section 101A, and the other end is positioned on the downstream side (outlet 111 side of the refrigerant) of the third heat exchange section 101C. The term “heat exchange section” is a section in the flow path 100 of the refrigerant specified by the position of the refrigerant in the flowing direction, and refers to a section from the position of the upstream end to the position of the downstream end of the region overlapping the heating element 5 in the XY plan view of FIGS. 1 and 2. The first heat exchange section 101A may be a section in which heat exchange for cooling the first heating element 5A disposed on the most upstream side is performed, and the third heat exchange section 101C may be a section in which heat exchange for cooling the third heating element 5C disposed on the most downstream side is performed. Between the first heat exchange section 101A and the third heat exchange section 101C, there is a second heat exchange section 101B in which the heat exchange for cooling the second heating element 5B is performed. In the following description, when referring to the ends of the heat exchange surfaces 411 and 412 and the other corrugated fins 4 in the flowing direction of the refrigerant, an end on the upstream side of the first heat exchange section 101A is referred to as an upstream end, and an end on the downstream side of the third heat exchange section 101C is referred to as a downstream end.

Dimensions related to a shape of the corrugated fin 4, such as a plate thickness D1 of the plate-shaped portion 410 and a gap (distance between opposing heat exchange surfaces) G1 between the adjacent plate-shaped portions 410, are not limited to specific dimensions. The plate thickness direction D1 of each plate-shaped portion 410 is not limited to the direction parallel to the flow path width direction (Y direction) as illustrated in FIG. 3B. For example, the corrugated fin 4 may be bent such that the gap G1 between the two plate-shaped portions 410 connected to one bent portion increases as going away from the bent portion. Furthermore, the shapes of the upper bent portion 420 and the lower bent portion 430 are not limited to specific shapes. The upper bent portion 420 and the lower bent portion 430 are not limited to the bent shape in which the cross-sectional shape is a U shape exemplified in FIG. 3B, and may be a bent shape or the like in which the cross-sectional shape is a U shape. Dimensions of the corrugated fin 4, such as the thickness D1 and the gap G1, and the bent shape can be set according to, for example, the size of the flow path 100 of the refrigerant, cooling performance required for the cooler 1, and the like.

Each of the upper bent portion 420 and the lower bent portion 430 is connected to the plate-shaped portion 410 over the entire section from the upstream end to the downstream end of the plate-shaped portion 410. The lower bent portion 430 of the corrugated fin 4 is in contact with the upper surface 301 of the bottom plate portion 300, and may be bonded to the upper surface 301 of the bottom plate portion 300 by a bonding material or by laser welding or ultrasonic joining, and may be fixed in the flow path 100 of the refrigerant. As illustrated in FIG. 3B, all the upper bent portions 420 of the corrugated fin 4 are in contact with the lower surface 201 of the top plate 2 in at least the third heat exchange section 101C downstream portion of the flow path 100 of the refrigerant in the cooler 1 of the present embodiment. Details regarding a contact state between the top plate 2 and the upper bent portion 420 of the corrugated fin 4 in the cooler 1 of the present embodiment will be described later with reference to FIGS. 5 to 10.

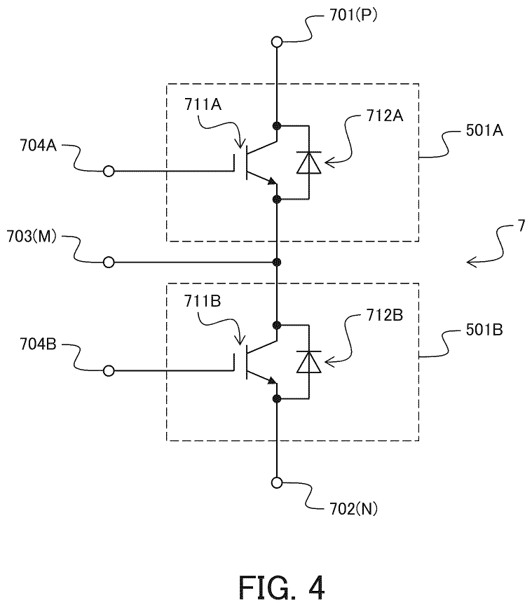

FIG. 4 is a circuit diagram illustrating a circuit configuration example of a semiconductor module including a heating element. As described above, the heating element 5 to be cooled by the cooler 1 may be a circuit component in which the semiconductor element 501 is disposed on the upper surface of the wiring board 500. The heating element 5 can be a circuit component that provides a half-bridge inverter circuit in a semiconductor module 7 as illustrated in FIG. 4. The heating element 5 may include a first switching element 711A and a second switching element 711B connected in series, and a first diode element 712A and a second diode element 712B connected in anti-parallel to each of the first switching element 711A and the second switching element 711B.

The wiring board 500 of the heating element 5 may be, for example, a direct copper bonding (DCB) substrate or an active metal brazing (AMB) substrate. A material and a forming method of the insulating substrate and the conductive plate in the wiring board 500 are not limited to a specific material and a forming method. The semiconductor element 501 may include one of the switching elements 711 connected in series and a diode element 712 connected in anti-parallel to the switching element 711. The switching element 711 may be, for example, an insulated gate bipolar transistor (IGBT) element, a power metal oxide semiconductor field effect transistor (MOSFET) element, a bipolar junction transistor (BJT) element, or the like. The diode element 712 may be, for example, a free wheeling diode (FWD) element, a Schottky barrier diode (SBD) element, a junction barrier Schottky (JBS) diode element, a merged PN Schottky (MPS) diode element, a PN diode element, or the like. The number, type, and layout of the semiconductor elements 501 arranged on the wiring board 500 are not limited to a specific number, type, and layout. For example, the semiconductor element 501 may include a semiconductor element in which the switching element 711 is formed and a semiconductor element in which the diode element 712 is formed. Furthermore, for example, a switching element (for example, first switching element 711A) illustrated as one element in FIG. 4 may be one in which the switching elements formed in a plurality of semiconductor elements 501 are connected in parallel.

When a half-bridge inverter circuit including the IGBT element as the switching element 711 is provided in the semiconductor module 7, the collector of the first switching element 711A is electrically connected to a first main terminal 701, and an emitter of the second switching element 711B is electrically connected to a second main terminal 702. The first main terminal 701 and the second main terminal 702 may be, for example, a P terminal connected to a positive electrode of a DC power supply and an N terminal connected to a negative electrode. The emitter of the first switching element 711A and the collector of the second switching element 711B are electrically connected to the third main terminal 703. The third main terminal 703 is connected to, for example, a load that consumes alternating current output by the half-bridge inverter circuit. The gate of the first switching element 711A and the gate of the second switching element 711B are electrically connected to a first control terminal 704A and a second control terminal 704B, respectively. In the semiconductor module 7 including the case 6, the first main terminal 701, the second main terminal 702, the third main terminal 703, the first control terminal 704A, and the second control terminal 704B are, for example, conductive plates called leads, and are integrally formed with the insulating resin portion of the case 6. The case 6 may be provided with an additional control terminal different from the control terminal 704. The additional control terminal may be, for example, a control terminal referred to as an auxiliary emitter terminal, an emitter sense terminal, or the like electrically connected to the emitter of the switching element 711. The auxiliary emitter terminal is connected to a gate drive circuit that generates a control signal to be applied to the gate of the switching element 711. The additional control terminal may include, for example, a temperature sensing terminal that is electrically connected to a temperature sensing unit that may be included in the semiconductor module 7 and measures the temperature of the semiconductor element. When a power MOSFET is used as the switching element 711, the collector and the emitter of the IGBT element described above are read as a drain and a source. Note that the circuit formed in the semiconductor module 7 is not limited to the half-bridge inverter circuit described above with reference to FIG. 4, and may be another circuit or a circuit including an inverter circuit and another circuit. In the semiconductor module 7, the case 6 may be omitted.

The cooler 1 of the present embodiment cools the heating element 5 by transferring heat generated in the heating element 5 to the top plate 2 and the corrugated fin 4 and dissipating the heat by heat exchange between the top plate 2 and the corrugated fin 4 and the refrigerant. Therefore, the temperature of the refrigerant flowing through the flow path 100 of the refrigerant gradually increases from the inlet 110 toward the outlet 111. Therefore, for example, when the plurality of semiconductor elements 501 arranged along flowing direction (X direction) of the refrigerant are caused to perform substantially the same operation while being cooled by the cooler 1, the efficiency of heat exchange at the position close to the outlet 111 is lower than the efficiency of heat exchange at the position close to the inlet 110. As a result, the temperature of the semiconductor element 501 close to the outlet 111 becomes higher than the temperature of the semiconductor element 501 close to the inlet 110, and the operation of each semiconductor element 501 may vary. In particular, when the plurality of heating elements 5A to 5C are arranged in the longitudinal direction (X direction) of the top plate 2 as illustrated in FIG. 1, the temperature difference between the first heating element 5A close to the inlet 110 and the third heating element 5C close to the outlet 120 tends to be large, and the variation in the operation of each heating element 5 tends to be large. In the cooler 1 of the present embodiment, the top plate 2 and the corrugated fins 4 are configured as described below with reference to FIGS. 5 to 10, so that the temperatures of the plurality of heating elements 5 arranged along flowing direction of the refrigerant can be made uniform.

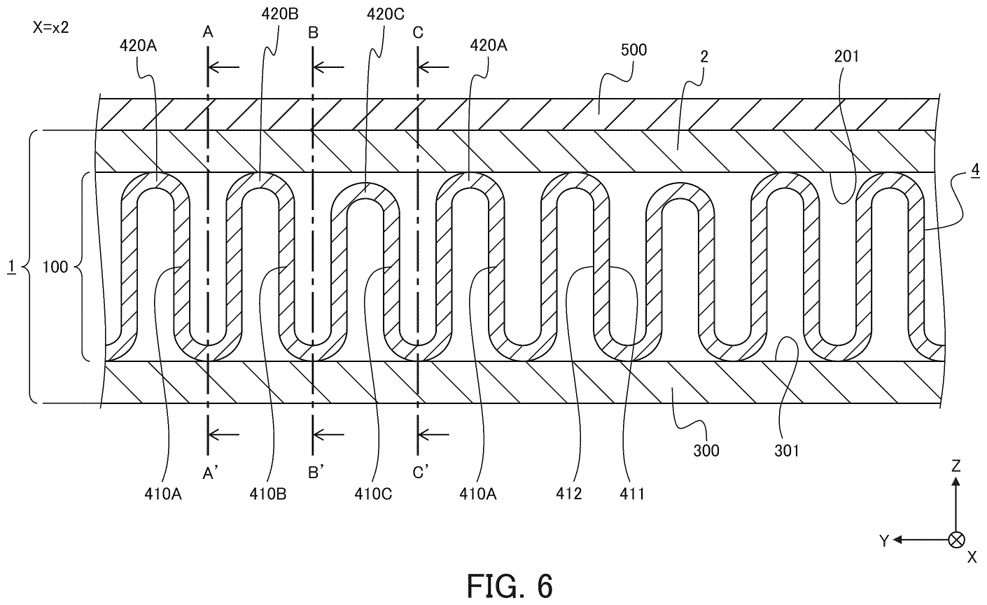

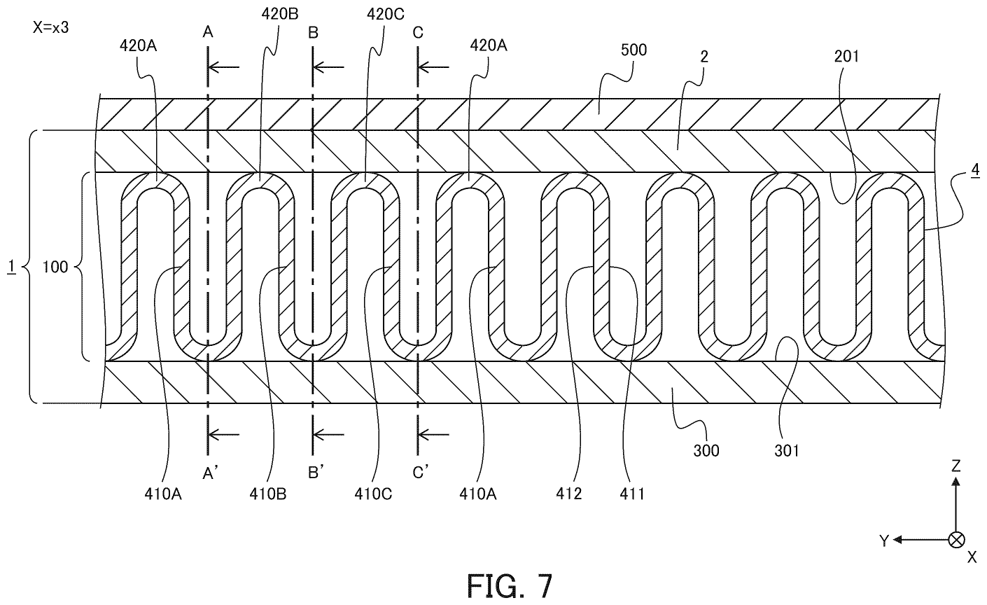

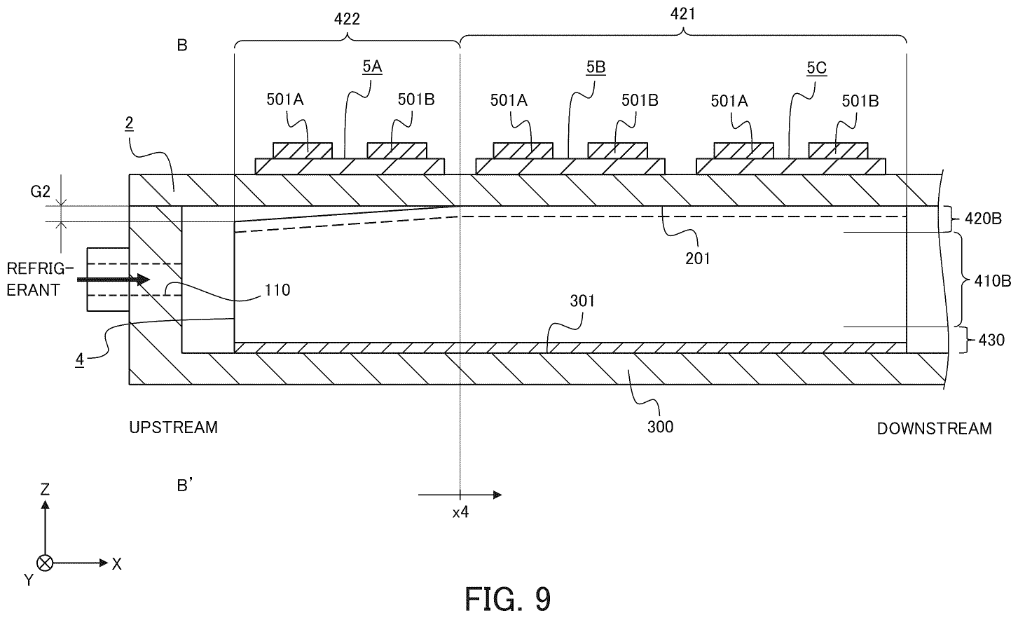

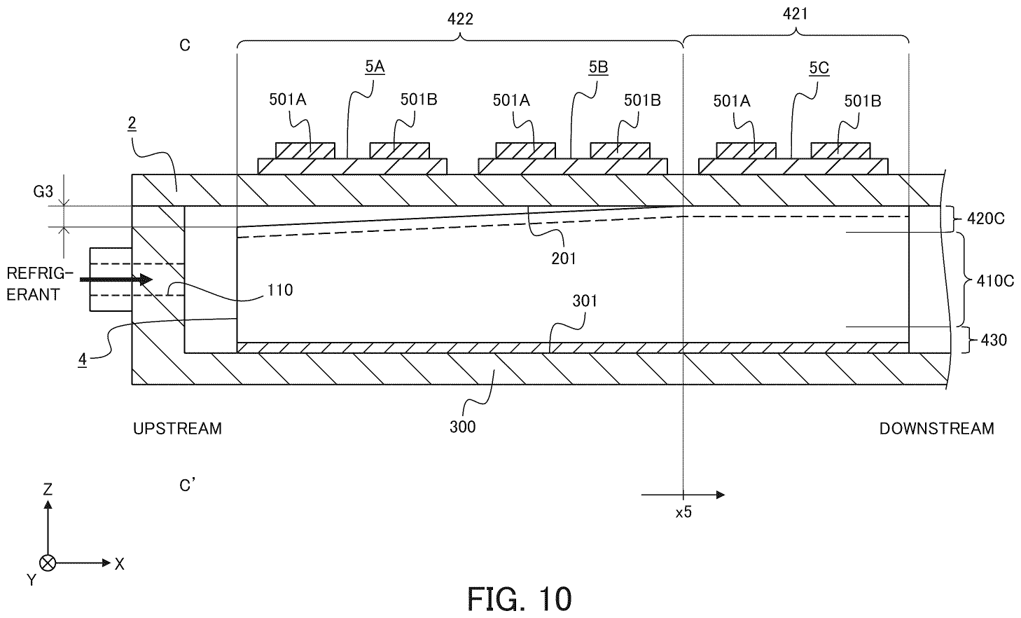

FIG. 5 is a sectional view illustrating a wave shape of the corrugated fin in the first heat exchange section of the upstream portion. FIG. 6 is a sectional view illustrating a wave shape of the corrugated fin in the second heat exchange section of the midstream portion. FIG. 7 is a sectional view illustrating a wave shape of a corrugated fin in the third heat exchange section in the downstream portion. FIG. 8 is a side sectional view illustrating a first contact state between the lower surface of the top plate and the upper bent portion of the corrugated fin. FIG. 9 is a side sectional view illustrating a second contact state between the lower surface of the top plate and the upper bent portion of the corrugated fin. FIG. 10 is a side sectional view illustrating a third contact state between the lower surface of the top plate and the upper bent portion of the corrugated fin.

The sectional view of FIG. 5 can be an enlarged view of a part of the sectional view of the cooler 1 taken along the YZ plane at a position x1 in the X direction illustrated in FIG. 2. The sectional view of FIG. 6 can be an enlarged view of a part of the cooler 1 taken along the YZ plane at a position x2 in the X direction illustrated in FIG. 2. FIG. 7 can be an enlarged view of a part of the cooler 1 taken along the YZ plane at a position x3 in the X direction illustrated in FIG. 2. The side sectional view of FIG. 8 is a view of a portion of the cooler 1 on the left side (positive side in the Y direction) with respect to the line A-A′ in FIG. 5, which is cut along the ZX plane including the line A-A′ in FIGS. 5 to 7, as viewed from the negative side in the Y direction. The side sectional view of FIG. 9 is a view of a portion of the cooler 1 on the left side (positive side in the Y direction) with respect to the line B-B′ in FIG. 5, which is cut along the ZX plane including the line B-B′ in FIGS. 5 to 7, as viewed from the negative side in the Y direction. The side sectional view of FIG. 10 is a view of a portion of the cooler 1 on the left side (positive side in the Y direction) with respect to the line C-C′ in FIG. 5, which is cut along the ZX plane including the line C-C′ in FIGS. 5 to 7, as viewed from the negative side in the Y direction. A broken line in the corrugated fin 4 in FIGS. 8 to 10 indicates a surface facing the upper surface 301 side of the bottom plate portion 300 at the top portion (portion in contact with the top plate 2) of the upper bent portion 420. Further, a position x4 in FIG. 9 and a position x5 in FIG. 10 correspond to the position x4 and the position x5 in the X direction illustrated in FIG. 2, respectively.

The contact state between the lower surface 201 of the top plate 2 and the upper bent portion 420 of the corrugated fin 4 in the cooler 1 of the present embodiment is roughly divided into three contact states. The first contact state is a state in which the entire section from the upstream end to the downstream end is in contact with the lower surface 201 of the top plate 2 as in the first upper bent portion 420A illustrated in FIGS. 5 to 7 and 8. The second contact state is a state in which a section from the upstream end to a position x4 between the first heat exchange section 101A and the second heat exchange section 101B is separated from the lower surface 201 of the top plate 2, and a section from the position x4 to the downstream end is in contact with the lower surface 201 of the top plate 2 as in the second upper bent portion 420B illustrated in FIGS. 5 to 7 and 9. The third contact state is a state in which a section from the upstream end to a position x5 between the second heat exchange section 101B and the third heat exchange section 101C is separated from the lower surface 201 of the top plate 2, and a section from the position x5 to the downstream end is in contact with the lower surface 201 of the top plate 2, as in the third upper bent portion 420C illustrated in FIGS. 5 to 7 and 10.

In the cooler 1 illustrated in FIGS. 9 and 10, the lower surface 201 of the top plate 2 is parallel to the upper surface 301 (XY plane) of the bottom plate portion 300. Therefore, as illustrated in FIG. 9, the shape of the second upper bent portion 420B of the corrugated fin 4 is formed such that the length (dimension in the flow path height direction (Z direction)) of the plate-shaped portion 410 is adjusted, the height (length of the fin) from the lower end of the lower bent portion 430 to the upper end of the second upper bent portion 420B gradually increases from the upstream end toward the position x4, and the height is constant in the section from the position x4 to the downstream end. Accordingly, when the section from the position x4 to the downstream end in the second upper bent portion 420B is brought into contact with the lower surface 201 of the top plate 2, the section from the upstream end to the position x4 in the second upper bent portion 420B is separated from the lower surface 201 of the top plate 2. The distance (gap) G2 from the lower surface 201 of the top plate 2 at the upstream end of the second upper bent portion 420B may be, for example, 1 μm to 2 μm, but is not limited to a specific distance. The distance G2 may be, for example, about 1% to 2% of the dimension of the flow path 100 of the refrigerant in the flow path height direction (or the height of the fin from the position x4 to the downstream end).

Similarly, as illustrated in FIG. 10, for example, the shape of the third upper bent portion 420C of the corrugated fin 4 is formed such that the length of the plate-shaped portion 410 is adjusted, the height from the lower end of the lower bent portion 430 to the upper end of the third upper bent portion 420C gradually increases from the upstream end toward the position x5, and the height is constant in the section from the position x5 to the downstream end. Accordingly, when the section from the position x5 to the downstream end in the third upper bent portion 420C is brought into contact with the lower surface 201 of the top plate 2, the section from the upstream end to the position x5 in the third upper bent portion 420C is separated from the lower surface 201 of the top plate 2. The distance (gap) G3 from the lower surface 201 of the top plate 2 at the upstream end of the third upper bent portion 420C may be, for example, 1 μm to 2 μm, but is not limited to a specific distance.

The distance G2 and the distance G3 described above may be the same or different. For example, an inclination angle of a section of the second upper bent portion 420B separated from the lower surface 201 of the top plate 2 with respect to the lower surface 201 may be the same as an inclination angle of a section of the third upper bent portion 420C separated from the lower surface 201 of the top plate 2 with respect to the lower surface 201. Furthermore, the number and arrangement order of the first upper bent portion 420A, the second upper bent portion 420B, and the third upper bent portion 420C in the corrugated fin 4 are not limited to a specific number and arrangement order. In the case of being roughly classified into the above-described three contact states, for example, the ratio of the upper bent portion 420 in contact with the lower surface 201 of the top plate 2 in the first heat exchange section 101A can be set to 5% to 10%, the ratio of the upper bent portion 420 in contact with the lower surface 201 of the top plate 2 in the second heat exchange section 101B can be set to 30% to 60%, and the ratio of the upper bent portion 420 in contact with the lower surface 201 of the top plate 2 in the third heat exchange section 101C can be set to 100%. Further, for example, the second upper bent portion 420B and the third upper bent portion 420C may be arranged only within a range in the flow path width direction (Y direction) overlapping a region where the heating element 5 is disposed in the XY plan view of FIGS. 1 and 2 in the corrugated fin 4. The upper bent portion 420 of the corrugated fin 4 illustrated in FIGS. 5 and 6 has a fin structure in which a contact state with the lower surface 201 of the top plate 2 is not uniform depending on a position in the flow path width direction (Y direction), and a portion (420A) in which the top portion of the upper bent portion 420 is in contact with the lower surface and a portion (420C) in which the top portion is separated from the lower surface 201 are mixed. However, the corrugated fin 4 is not limited to such a structure, and for example, the corrugated fin 4 may be formed only of a fin in which the top portion of the upper bent portion 420 is separated from the lower surface 201 in the upstream portion.

The corrugated fin 4 according to the present embodiment can be easily formed, for example, by changing the shape of a mold used when forming the corrugated fin 4 by press working to a shape capable of forming the second upper bent portion 420B and the third upper bent portion 420C described above. The method for forming the corrugated fin 4 is not limited to a specific method.

The direct heat transfer from the top plate 2 to the upper bent portion 420 of the corrugated fin 4 occurs in a region (heat contact region 421) of the upper bent portion 420 that is in contact with the top plate 2. The entire region from the upstream end to the downstream end of the first upper bent portion 420A is the heat contact region 421 when viewed in the flowing direction (X direction) of the refrigerant. On the other hand, in the second upper bent portion 420B and the third upper bent portion 420C, when viewed in the flowing direction of the refrigerant, there is a heat insulating region 422 on the upstream side of the heat contact region 421, in which the direct heat transfer from the top plate 2 is blocked by the refrigerant flowing between the upper surface of the upper bent portion 420 and the lower surface 201 of the top plate 2. That is, in the cooler 1 of the present embodiment, the number (area) of the heat contact regions 421 viewed in the flow path width direction (Y direction) increases from the upstream to the downstream. In other words, in the cooler 1 of the present embodiment, the fins (plate-shaped portions 410) are arranged at the same interval G1 (refer to FIG. 3B) from upstream to downstream, and the area of the heat contact region 421 in a plan view of the lower surface 201 of the top plate 2 gradually increases from upstream to downstream.

The heat moved from the top plate 2 to the upper bent portion 420 is further moved (transferred) to the plate-shaped portion 410 connected to the upper bent portion 420, and is dissipated into the refrigerant by heat exchange between the heat exchange surfaces 411 and 412 of the plate-shaped portion 410 and the refrigerant. In the plate-shaped portion 410A connected to the first upper bent portion 420A, since heat transfer from the first upper bent portion 420A occurs in the entire region from the upstream end to the downstream end, the entire region from the upstream end to the downstream end can be regarded as the heat contact region 421. On the other hand, in the plate-shaped portion 410B connected to the second upper bent portion 420B, a region from the upstream end to the position x4 can be regarded as the heat insulating region 422, and a region from the position x4 to the downstream end can be regarded as the heat contact region 421. Similarly, in the plate-shaped portion 410C connected to the third upper bent portion 420C, a region from the upstream end to the position x5 can be regarded as the heat insulating region 422, and a section from the position x5 to the downstream end can be regarded as the heat contact region 421.

In the first heat exchange section 101A in the upstream portion of the flow path 100 of the refrigerant, as illustrated in FIG. 5, only the first upper bent portion 420A is in contact with the lower surface 201 of the top plate 2, and the second upper bent portion 420B and the third upper bent portion 420C are separated from the lower surface 201 of the top plate 2. That is, in the first heat exchange section 101A, heat exchange effective for cooling the heating element 5 is performed only between the refrigerant and the plate-shaped portion 410A connected to the first upper bent portion 420A, and heat exchange is not substantially performed between the other plate-shaped portions 410B and 410C and the refrigerant. Therefore, out of the refrigerant flowing in the first heat exchange section 101A, the refrigerant flowing between the adjacent plate-shaped portions 410B connected to the second upper bent portion 420B and the refrigerant flowing between the adjacent plate-shaped portions 410C connected to the third upper bent portion 420C flow into the second heat exchange section 101B at a lower temperature as compared with the refrigerant flowing along the heat exchange surfaces 411 and 412 of the plate-shaped portion 410A connected to the first upper bent portion 420A.

In the second heat exchange section 101B, as illustrated in FIG. 6, the first upper bent portion 420A and the second upper bent portion 420B are in contact with the lower surface 201 of the top plate 2, and the third upper bent portion 420C is separated from the lower surface 201 of the top plate 2. That is, in the second heat exchange section 101B, heat exchange effective for cooling the heating element 5 is performed between the plate-shaped portion 410A connected to the first upper bent portion 420A and the refrigerant, and between the plate-shaped portion 410B connected to the second upper bent portion 420B and the refrigerant, and heat exchange is not substantially performed between the plate-shaped portion 410C connected to the third upper bent portion 420C and the refrigerant. As described above, the temperature of the refrigerant that exchanges heat with the plate-shaped portion 410A connected to the first upper bent portion 420A is increased by the heat exchange in the first heat exchange section 101A, but the temperature of the refrigerant that exchanges heat with the plate-shaped portion 410B connected to the second upper bent portion 420B remains relatively low. Therefore, the efficiency of heat exchange between the plate-shaped portion 410B and the refrigerant is higher than the efficiency of heat exchange between the plate-shaped portion 410A and the refrigerant. Therefore, the difference between the temperature of the semiconductor element 501 of the second heating element 5B cooled by the heat exchange in the second heat exchange section 101B and the temperature of the semiconductor element 501 of the first heating element 5A cooled by the heat exchange in the first heat exchange section 101A can be reduced. Among the refrigerant flowing in the second heat exchange section 101B, the refrigerant flowing between the adjacent plate-shaped portions 410C connected to the third upper bent portion 420C flows into the third heat exchange section 101C at a lower temperature as compared with the refrigerant flowing along the heat exchange surfaces 411 and 412 of the plate-shaped portion 410A connected to the first upper bent portion 420A and the refrigerant flowing along the heat exchange surfaces 411 and 412 of the plate-shaped portion 410B connected to the second upper bent portion 420B.

In the third heat exchange section 101C, as illustrated in FIG. 7, all of the first upper bent portion 420A, the second upper bent portion 420B, and the third upper bent portion 420C are in contact with the lower surface 201 of the top plate 2. That is, in the third heat exchange section 101C, heat exchange effective for cooling the heating element 5 is performed between the plate-shaped portion 410A connected to the first upper bent portion 420A and the refrigerant, between the plate-shaped portion 410B connected to the second upper bent portion 420B and the refrigerant, and between the plate-shaped portion 410B connected to the third upper bent portion 420C and the refrigerant. At this time, the efficiency of heat exchange between the plate-shaped portion 410C and the refrigerant is higher than the efficiency of heat exchange between the plate-shaped portion 410A and the refrigerant and the efficiency of heat exchange between the plate-shaped portion 410B and the refrigerant. Therefore, the difference between the temperature of the semiconductor element 501 of the third heating element 5C cooled by the heat exchange in the third heat exchange section 101C and the temperature of the semiconductor element 501 of the second heating element 5B cooled by the heat exchange in the second heat exchange section 101B can be reduced.

In the cooler 1 of the present embodiment, the upper bent portion 420 of the corrugated fin 4 is divided into an upper bent portion 420A that is in contact with the lower surface 201 of the top plate 2 from the upstream end to the downstream end, and the upper bent portions 420B and 420C that are inclined in a direction away from the lower surface 201 toward the upstream side of the section in contact with the lower surface 201 of the top plate 2, so that the heat insulating region 422 is provided in the first heat exchange section 101A in the upstream portion and the second heat exchange section 101B in the midstream portion among the three heat exchange sections 101A to 101C arranged in the flowing direction of the refrigerant. Therefore, in the cooler 1 of the present embodiment, the area of the heat contact region 421 in a plan view of the lower surface 201 of the top plate 2 can be increased stepwise from upstream to downstream while the fins (plate-shaped portions 410) are arranged at the same interval G1 (refer to FIG. 3B) from the upstream to the downstream. That is, the cooler 1 of the present embodiment can increase the area of the heat contact region 421 stepwise from the upstream to the downstream without changing the arrangement density of the fins (plate-shaped portions 410) as viewed in the flowing direction (X direction) of the refrigerant. Therefore, as compared with the semiconductor cooling device in which the arrangement density of fins increases from the upstream to the downstream as exemplified in JP 2010-153785 A, it is possible to reduce the temperature difference of the heating element 5 while suppressing an increase in pressure loss in the downstream portion. The arrangement density of the fins is the number of fins per unit length in the flow path width direction (Y direction) in the cooler cross section viewed from flowing direction of the refrigerant (X direction). In the cooler 1 of the present embodiment, the number of fins (plate-shaped portions 410) contributing to the heat exchange with the refrigerant in the heat exchange section of the upstream portion is made smaller than the number in the downstream portion by providing the heat insulating region 422, and the temperature rise due to the heat exchange of the refrigerant flowing between the fins is suppressed. Therefore, as compared with the semiconductor cooling device exemplified in JP 2010-153785 A in which the clearance between the fin protruding from the lower surface of the metal base and the flow path cover decreases from the upstream to the downstream, for example, it is possible to suppress an increase in the dimension in the flow path height direction (Z direction), to suppress a decrease in the degree of freedom of the installation place of the semiconductor module to which the cooler 1 is attached, and to suppress an increase in the weight of the device in which the semiconductor module to which the cooler 1 is attached is installed.

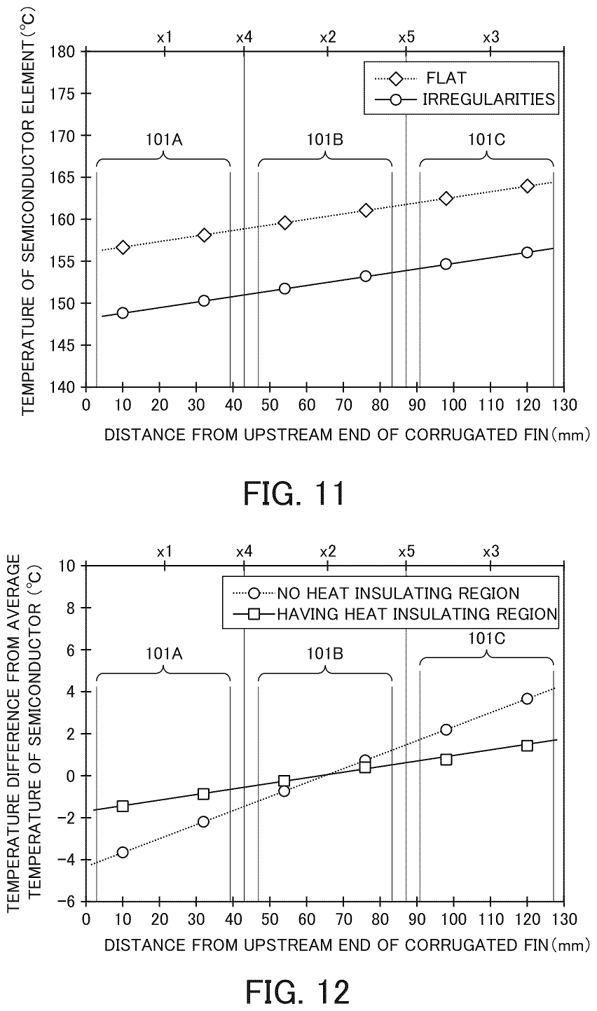

FIG. 11 is a graph illustrating a relationship between a shape of the corrugated fin and a temperature of a semiconductor element. FIG. 12 is a graph illustrating a relationship between presence or absence of a heat insulating region and the temperature of the semiconductor element.

The shape of the corrugated fin 4 used in the cooler 1 of the present embodiment is not limited to a specific shape as described above. For example, in the corrugated fin 4, the heat exchange surfaces 411 and 412 of the plate-shaped portion 410 may have irregularities. The unevenness of the heat exchange surfaces 411 and 412 may be generated by forming dimples, grooves, or the like on the heat exchange surfaces 411 and 412 by, for example, press working, etching, or the like, or may be generated by bending (curving) the plate-shaped portion 410. When the corrugated fins 4 having irregularities on the heat exchange surfaces 411 and 412 are arranged in the refrigerant flow paths 100, turbulence occurs in the refrigerant flowing along the heat exchange surfaces 411 and 412 due to the irregularities of the heat exchange surfaces 411 and 412, and for example, the refrigerant having a relatively high temperature flowing at a position close to the top plate 2 and the refrigerant having a relatively low temperature flowing at a position close to the bottom plate portion 300 are stirred. Therefore, the temperature of the refrigerant that exchanges heat with the portion of the plate-shaped portion 410 close to the top plate 2, which is at a relatively high temperature, can be lowered, and the efficiency of heat exchange can be further increased as compared with the plate-shaped portion 410 in which the heat exchange surfaces 411 and 412 illustrated in FIGS. 3A and 3B and the like are flat. The graph of FIG. 11 illustrates a comparative example of the cooling efficiency of the cooler 1 in which the corrugated fins 4 having flat heat exchange surfaces 411 and 412 are arranged and the cooling efficiency of the cooler 1 in which the corrugated fins 4 having irregularities on the heat exchange surfaces 411 and 412 are arranged. In the graph of FIG. 11, the horizontal axis represents the distance from the upstream end of the corrugated fin 4, and the vertical axis represents the temperature of the semiconductor element 501. x1 to x5 on the horizontal axis on the upper side are positions x1 to x5 in the X direction illustrated in FIG. 2. A rhombus mark in the graph exemplifies the relationship between the position and the temperature of the semiconductor element 501 when the corrugated fin 4 having the flat heat exchange surfaces 411 and 412 is disposed, and a circle mark exemplifies the relationship between the position and the temperature of the semiconductor element 501 when the corrugated fin 4 having irregularities on the heat exchange surfaces 411 and 412 is disposed. The position of the semiconductor element 501 can be a distance from the upstream end of the corrugated fin to the center of the semiconductor element 501 when the six semiconductor elements 501 are arranged in the flowing direction (X direction) of the refrigerant as illustrated in FIG. 1. In any case where the corrugated fins are arranged, the temperature of the semiconductor element 501 is higher as the distance from the upstream end is longer. However, the temperature of each semiconductor element 501 in a case where the corrugated fins 4 having irregularities are arranged on the heat exchange surfaces 411 and 412 is lower as a whole than the temperature of each semiconductor element 501 in a case where the corrugated fins 4 having flat heat exchange surfaces 411 and 412 are arranged. The graph of FIG. 11 merely illustrates an example of the temperature difference between the case where the heat exchange surfaces 411 and 412 have irregularities and the case where the heat exchange surfaces are flat without irregularities. How much the temperature of the semiconductor element 501 can be lowered can depend on the type of the semiconductor element 501, what kind of irregularities are provided on the heat exchange surfaces 411 and 412, and the like.

Furthermore, the graph of FIG. 12 illustrates a comparative example of the cooling efficiency in a case where the heat insulating region 422 described above is not provided in the corrugated fin 4 and the cooling efficiency in a case where the heat insulating region 422 is provided. In the graph of FIG. 12, the horizontal axis represents the distance from the upstream end of the corrugated fin 4, and the vertical axis represents the temperature difference from the average temperature of the semiconductor element 501. The average temperature of the semiconductor elements 501 can be an average value of the temperatures of the six semiconductor elements 501 arranged in the flowing direction of the refrigerant (X direction). A circle in the graph indicates the relationship between the position of the semiconductor element 501 and the temperature when the heat insulating region 422 is not provided, and a square indicates the relationship between the position of the semiconductor element 501 and the temperature when the heat insulating region 422 is provided. When the heat insulating region 422 is provided, the semiconductor element 501 in the third heat exchange section 101C can be cooled by the refrigerant that has passed through the first heat exchange section 101A and the second heat exchange section 101B while the temperature is relatively low. Therefore, in a case where the heat insulating region 422 is provided, the variation in temperature among the six semiconductor elements 501 can be reduced, in other words, the temperatures of the plurality of semiconductor elements 501 can be made uniform, as compared with a case where the heat insulating region 422 is not provided. In both the case where the heat exchange surfaces 411 and 412 have irregularities and the case where the heat exchange surfaces are flat without irregularities, it can be expected that the temperature of the semiconductor element 501 can be made uniform equivalent to the graph of FIG. 12.

In the cooler 1 of the present embodiment described above, in order to increase the contact area between the upper bent portion 420 of the corrugated fin 4 and the lower surface 201 of the top plate 2 from the upstream to the downstream, some plate-shaped portions 410 of the plurality of plate-shaped portions 410 in the corrugated fin 4 have a shape having a heat insulating region 422 that blocks the direct heat transfer from the top plate 2 on the upstream side of the heat contact region 421 where the direct heat transfer from the top plate 2 occurs. Specifically, the heat insulating region 422 separated from the lower surface 201 is provided by, for example, inclining the upper bent portion 420 positioned between the plate-shaped portion 410 and the top plate 2 in the corrugated fin 4 with respect to the lower surface 201 of the top plate 2, and the number of the heat contact regions 421 at each position in the flowing direction (X direction) of the refrigerant increases from the upstream to the downstream. Therefore, the temperatures of the plurality of semiconductor elements 501 arranged along the flowing direction of the refrigerant can be made uniform without changing the arrangement density of the fins (plate-shaped portions 410) between the upstream portion and the downstream portion. In addition, the corrugated fin 4 provided with the heat insulating regions 422 corresponding to the number and layout of the heating elements 5 arranged on the upper surface 200 of the top plate 2 may be arranged in the flow path 100 of the refrigerant, and versatility of the top plate 2 and the water jacket 3 is high. Therefore, as for the cooler 1 according to the present embodiment, it is possible to easily and inexpensively manufacture the cooler 1 capable of uniformizing the temperatures of the plurality of semiconductor elements 501, as compared with a cooler in which heat radiation fins arranged such that the density increases from the upstream to the downstream of the flow path of the refrigerant are integrally formed with the top plate as in JP 2010-153785 A. In the cooler of JP 2010-153785 A, the pressure loss changes according to the change in the density of the heat radiating fins, whereas in the cooler 1 of the present embodiment, the arrangement density (arrangement interval) of the plate-shaped portions 410 of the corrugated fin 4 in the flowing direction of the refrigerant is constant from the upstream end to the downstream end, and the pressure loss of the refrigerant flowing along the plate-shaped portions 410 does not substantially change. Therefore, the cooler 1 of the present embodiment can suppress a decrease in cooling performance due to a change in the pressure loss.

### Second Embodiment

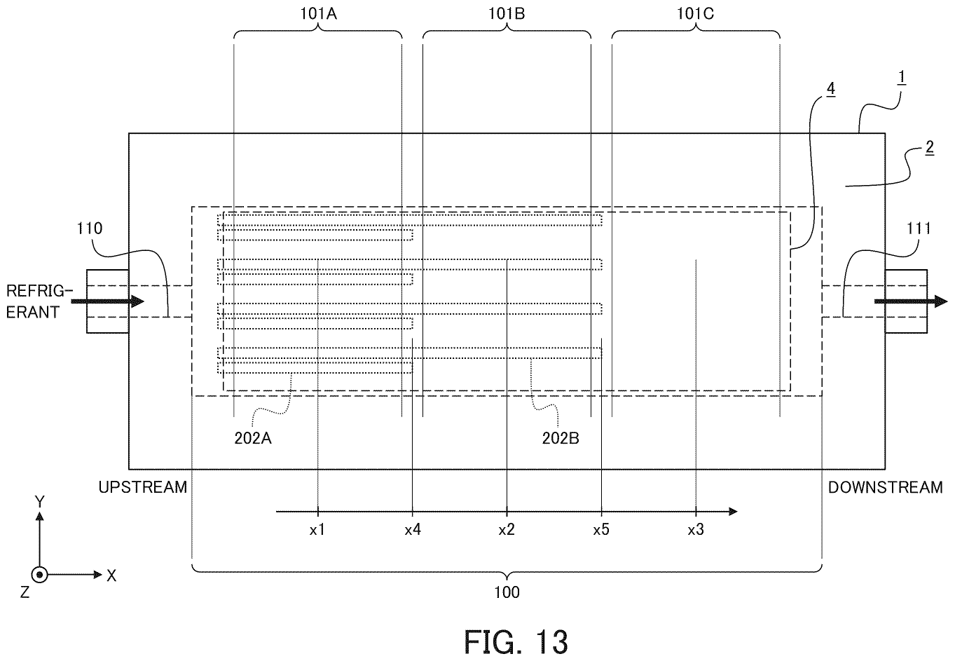

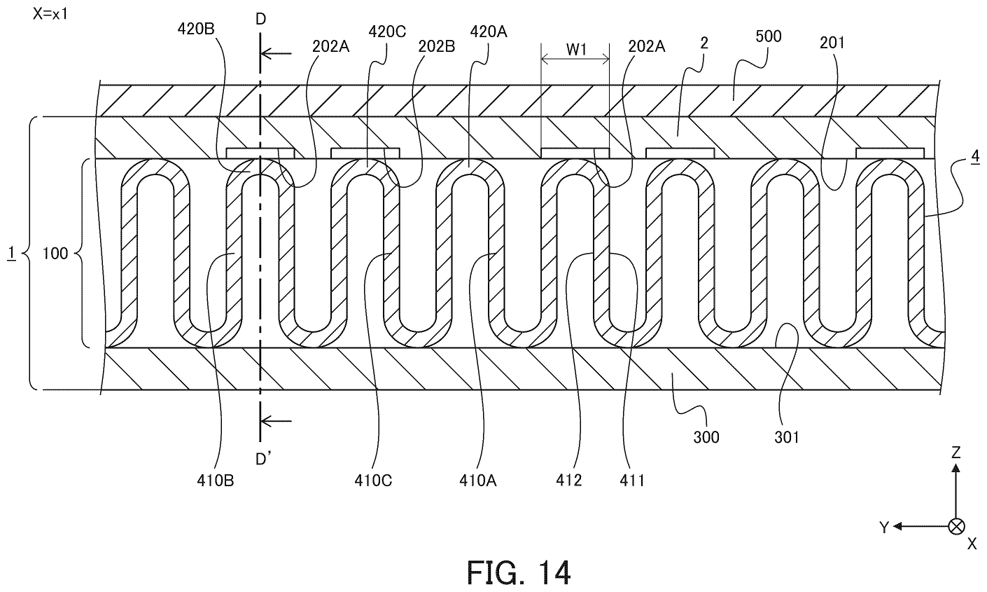

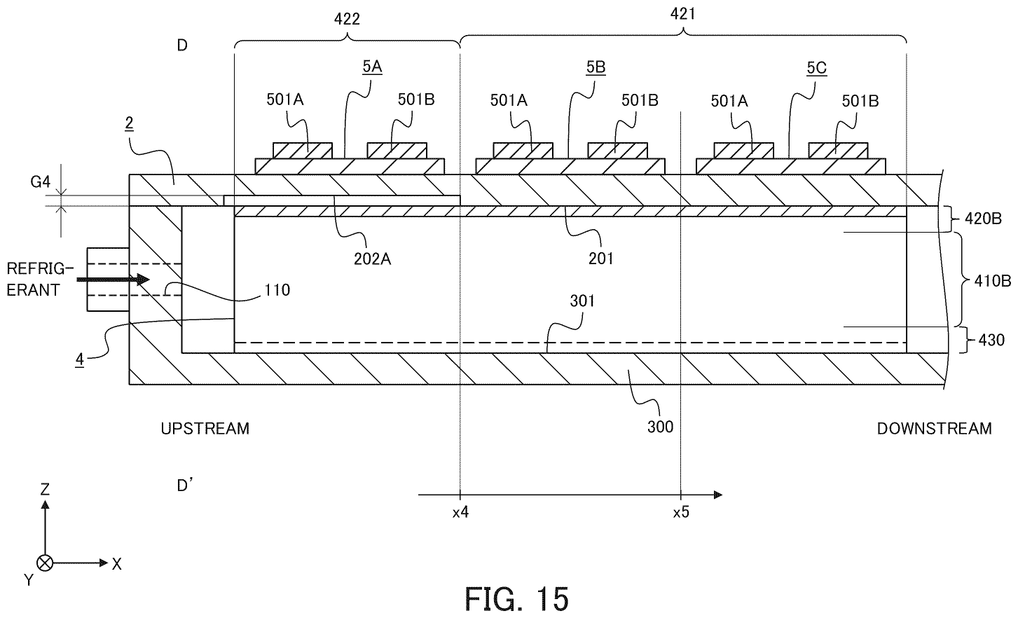

FIG. 13 is a plan view of a cooler according to a second embodiment. FIG. 14 is a side sectional view illustrating a wave shape of the corrugated fin and a shape of a lower surface of the top plate. FIG. 15 is a side sectional view illustrating the second contact state between the lower surface of the top plate and the upper bent portion of the corrugated fin. The side sectional view of FIG. 14 can be an enlarged view of a part of the cooler 1 cut along the YZ plane at the position x1 in the first heat exchange section 101A of the upstream portion exemplified in FIG. 13. The side sectional view of FIG. 15 is a view of the portion of the cooler 1 on the left side (positive side in the Y direction) with respect to the line D-D′ in FIG. 14, which is cut along the ZX plane including the line D-D′ in FIG. 14, as viewed from the negative side in the Y direction. A broken line in the corrugated fin 4 of FIG. 15 indicates a surface facing the lower surface 201 side of the top plate 2 at the top portion (a portion in contact with the upper surface 301 of the bottom plate portion 300) of the lower bent portion 430.

In the cooler 1 of the present embodiment, as illustrated in FIGS. 13 to 15, grooves 202A and 202B that separate the upper bent portion 420 of the corrugated fin 4 from the lower surface 201 are formed in the lower surface 201 of the top plate 2 so that the contact area between the upper bent portion 420 of the corrugated fin 4 and the lower surface 201 of the top plate 2 increases from the upstream to the downstream. The groove 202 is formed in a region overlapping the upper bent portion 420 of the corrugated fin 4 and the heat insulating region 422 provided in the plate-shaped portion 410 in a plan view of the lower surface 201 of the top plate 2. That is, also in the cooler 1 of the present embodiment, the number of the heat contact regions 421 at each position in the flowing direction (X direction) of the refrigerant can be increased from the upstream to the downstream without changing the arrangement density of the fins (plate-shaped portions 410) between the upstream portion and the downstream portion. In the corrugated fin 4 according to the present embodiment, the heights of the second upper bent portion 420B and the third upper bent portion 420C described in the first embodiment from the upper surface 301 of the bottom plate portion 300 may be constant from the upstream end to the downstream end in the flowing direction (X direction) of the refrigerant, similarly to the first upper bent portion 420A. That is, the second upper bent portion 420B and the third upper bent portion 420C in the corrugated fin 4 according to the present embodiment may not have a shape in which the upper bent portion 420 is inclined in order to provide the heat insulating region 422 (refer to FIGS. 9 and 10). In the plate-shaped portion 410 of the corrugated fin 4 according to the present embodiment, the heat exchange surfaces 411 and 412 may be flat or may have irregularities.

As described in the first embodiment, the entire region of the first upper bent portion 420A from the upstream end to the downstream end in the flowing direction of the refrigerant is set as the heat contact region 421. Therefore, a groove for separating the top plate 2 from the first upper bent portion 420A is not formed in a region of the lower surface 201 of the top plate 2 overlapping the first upper bent portion 420A in a plan view of the lower surface 201.

As described in the first embodiment, in the second upper bent portion 420B, a portion from the upstream end in the flowing direction of the refrigerant to the position x4 between the first heat exchange section 101A and the second heat exchange section 101B is set as the heat insulating region 422, and a portion from the position x4 to the downstream end is set as the heat contact region 421. Therefore, in a region of the lower surface 201 of the top plate 2 overlapping the second upper bent portion 420B in a plan view, a first groove 202A extending from the position of the upstream end of the second upper bent portion 420B in the flowing direction of the refrigerant to the position x4 is formed. As described in the first embodiment, in the third upper bent portion 420C, a portion from the upstream end in the flowing direction of the refrigerant to the position x5 between the second heat exchange section 101B and the third heat exchange section 101C is set as the heat insulating region 422, and a portion from the position x5 to the downstream end is set as the heat contact region 421. Therefore, in a region of the lower surface 201 of the top plate 2 overlapping the third upper bent portion 420C in a plan view, a second groove 202B extending from the position of the upstream end of the third upper bent portion 420C in the flowing direction of the refrigerant to the position x5 is formed. In the first groove 202A and the second groove 202B, as in the first groove 202A illustrated in FIG. 15, the position of the upstream end of the groove 202 in the flowing direction of the refrigerant may be on the upstream side (negative side in the X direction) of the positions of the upstream ends of the second upper bent portion 420B and the third upper bent portion 402C.

The groove 202 may be formed to have a depth (dimension in the Z direction) G4 and a width (dimension in the Y direction) W1 at which the heat insulating regions 422 of the second upper bent portion 420B and the third upper bent portion 420C are not in contact with the top plate 2. The depth G4 of the groove 202 formed in the lower surface 201 of the top plate 2 may be, for example, 1 μm to 2 μm, but is not limited to a specific depth. The width W1 of the groove 202 may be, for example, 0.1 to 1.0 mm, but is not limited to a specific width. The groove 202 can be easily formed by, for example, known milling, cutting such as rooting, or pressing. The number and arrangement order of the first grooves 202A and the second grooves 202B formed on the lower surface 201 of the top plate 2 are not limited to a specific number and arrangement order. The shape of the groove 202 is not limited to a shape having a flat bottom surface, and may be, for example, a shape having a concave curved surface corresponding to the upper surface (convex curved surface) of the upper bent portion 420. Furthermore, the groove 202 may be formed, for example, such that the depth G4 becomes shallower and/or the width W1 becomes narrower from the upstream to the downstream. Furthermore, on the lower surface 201 of the top plate 2, for example, a groove having a concave shape corresponding to the convex shape of the heat contact region 421 of the upper bent portion 420 and for securing a contact area with the heat contact region 421 may be formed, and a groove 202 for separating the upper bent portion 420 from the top plate 2 may be formed on the upstream side of the groove. In addition, the grooves 202 in the cooler 1 according to the present embodiment may be provided at positions corresponding to all the upper bent portions 420 of the corrugated fin 4 in a cross section perpendicular to the flowing direction (X direction) of the refrigerant.

In the cooler 1 of the present embodiment, the number, formation positions, dimensions, and the like of the grooves 202 on the lower surface 201 may be changed according to the number and layout of the heating elements 5 arranged on the upper surface 200 of the top plate 2, and versatility of the water jacket 3 and the corrugated fin 4 is high. Therefore, for example, it is possible to easily and inexpensively manufacture the cooler 1 capable of uniformizing the temperatures of the plurality of semiconductor elements 501, as compared with a cooler in which heat radiation fins arranged such that the density increases from the upstream to the downstream of the flow path of the refrigerant are integrally formed with the top plate as in JP 2010-153785 A.

### Third Embodiment

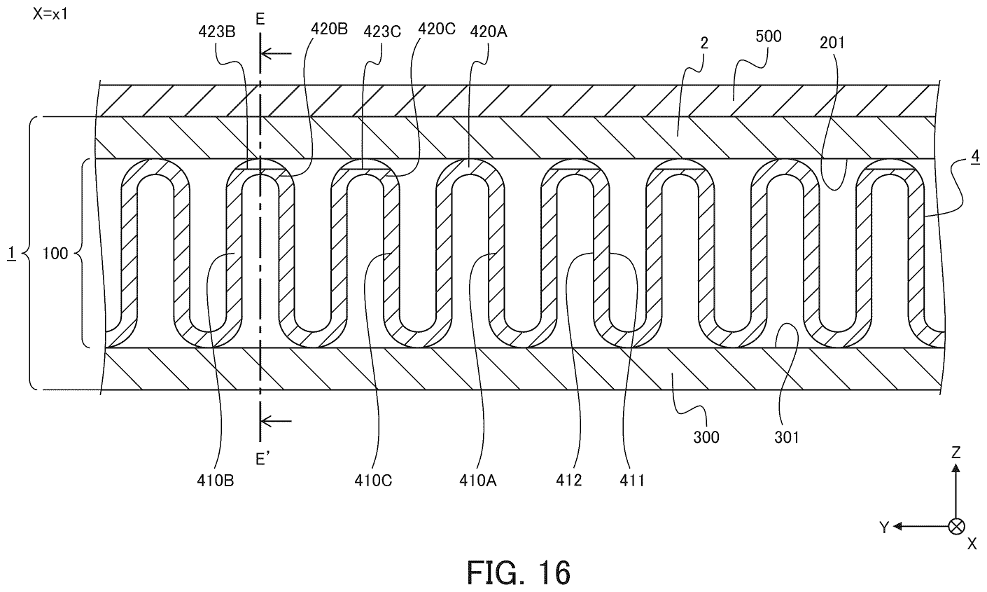

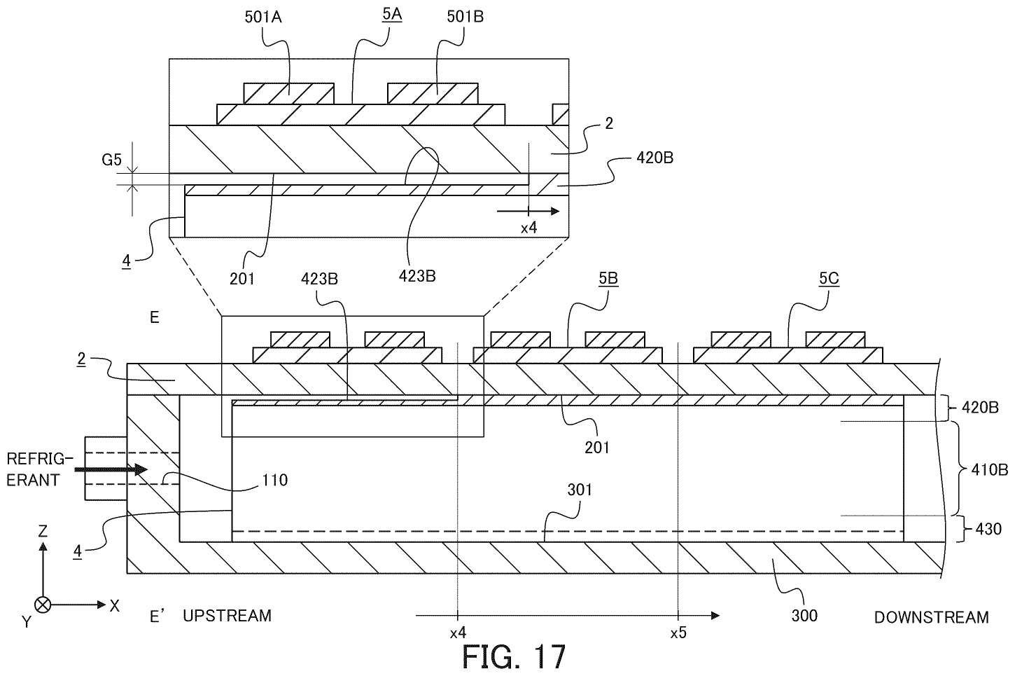

FIG. 16 is a side sectional view illustrating a wave shape of the corrugated fin and a shape of the lower surface of the top plate in the cooler according to a third embodiment. FIG. 17 is a side sectional view illustrating the second contact state between the lower surface of the top plate and the upper bent portion of the corrugated fin. The side sectional view of FIG. 16 can be an enlarged view of a part of the cooler 1 cut along the YZ plane at the position x1 in the first heat exchange section 101A of the upstream portion exemplified in FIG. 2. The side sectional view of FIG. 17 is a portion of the cooler 1 on the left side (positive side in the Y direction) with respect to the line E-E′ in FIG. 16, which is cut along the ZX plane including the line E-E′ in FIG. 16, as viewed from the negative side in the Y direction. A broken line in the corrugated fin 4 of FIG. 17 indicates a surface facing the lower surface 201 side of the top plate 2 at the top portion (a portion in contact with the upper surface 301 of the bottom plate portion 300) of the lower bent portion 430.

In the cooler 1 of the present embodiment, in order to increase the contact area between the upper bent portion 420 of the corrugated fin 4 and the lower surface 201 of the top plate 2 from the upstream to the downstream, as illustrated in FIGS. 16 and 17, the tops of the regions to be the heat insulating regions 422 in some upper bent portions 420 of the corrugated fin 4 are flattened by cutting, polishing, or the like and separated from the lower surface 201 of the top plate 2. That is, also in the cooler 1 of the present embodiment, the number (area) of the heat contact regions 421 at each position in the flowing direction (X direction) of the refrigerant can be increased from the upstream to the downstream without changing the arrangement density of the fins (plate-shaped portions 410) between the upstream portion and the downstream portion. In the corrugated fin 4 according to the present embodiment, all the upper bent portions 420 are formed so that the height (fin length) from the upper surface 301 of the bottom plate portion 300 is constant from the upstream end to the downstream end, and then flat surfaces 423B and 423C are formed by cutting, polishing, or the like in the portions to be the heat insulating regions in the second upper bent portion 420B and the third upper bent portion 420C. The flat surface 423B of the second upper bent portion 420B is formed, for example, from an upstream end in the flowing direction (X direction) of the refrigerant to a position x4 between the first heat exchange section 101A and the second heat exchange section 101B. The flat surface 423C of the third upper bent portion 420C is formed, for example, from an upstream end in the flowing direction of the refrigerant to a position x5 between the second heat exchange section 101B and the third heat exchange section 101C. In the cooler 1 of the present embodiment, the lower surface 201 of the top plate 2 can be a flat surface parallel to the upper surface of the bottom plate portion 300 similarly to the cooler 1 of the first embodiment. Therefore, in the corrugated fin 4 according to the present embodiment, the length of the fin of the heat insulating region 422 is shorter than that of the heat contact region 421, and a gap is formed between a tip of the region to be the heat insulating region 422 of the second upper bent portion 420B and the third upper bent portion 420C and the lower surface 201 of the top plate 2.

For example, the flat surface 423 can be formed such that a step (in other words, distance G5 from flat surface 423 to lower surface 201 of top plate 2 in heat insulating region 422 illustrated in FIG. 17) generated at a boundary between the heat insulating region 422 and the heat contact region 421 is 1 μm to 2 μm. The flat surface 423 can be easily formed by, for example, known milling, rooter processing, or the like. In addition, for example, the shape of the mold used in the step of forming the corrugated fin 4 by press working may be changed to a shape having a portion to be flattened by crushing a portion to be the heat insulating region 422 in the upper bent portion 420, and the flat surface 423 may be formed by press working. In the plate-shaped portion 410 of the corrugated fin 4 according to the present embodiment, the heat exchange surfaces 411 and 412 may be flat or may have irregularities.

The number and arrangement order of the first upper bent portion 420A, the second upper bent portion 420B, and the third upper bent portion 420C in the corrugated fin 4 according to the present embodiment are not limited to a specific number and arrangement order. For example, the flat surface 423 may be formed such that the distance G5 between the flat surface and the lower surface 201 of the top plate 2 decreases from the upstream to the downstream.

### Fourth Embodiment

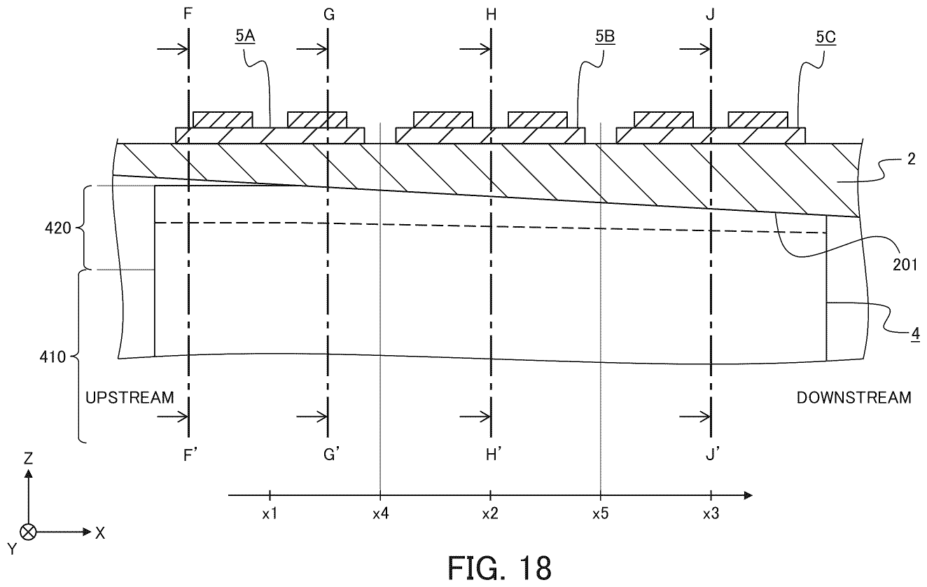

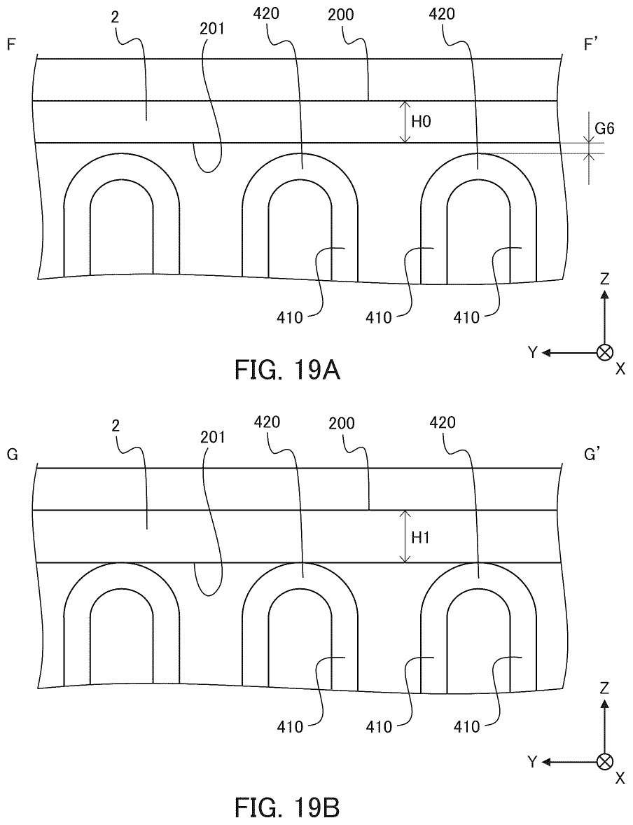

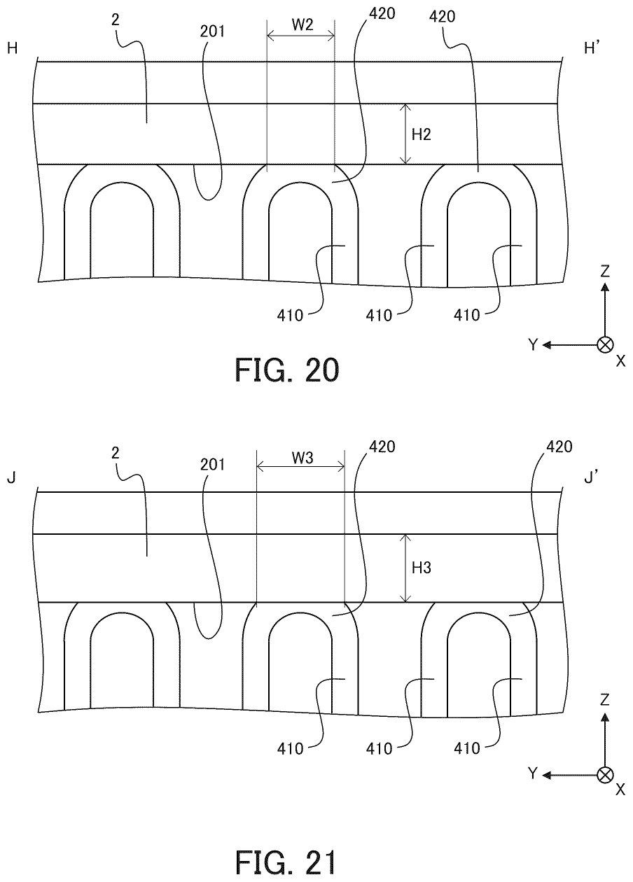

FIG. 18 is a side sectional view illustrating a wave shape of the corrugated fin and a shape of the lower surface of the top plate in the cooler according to a fourth embodiment. FIGS. 19A and 19B are side sectional views illustrating a contact state between the lower surface of the top plate and the upper bent portion of the corrugated fin in the first heat exchange section of an upstream portion. FIG. 20 is a side sectional view illustrating a contact state between the lower surface of the top plate and the upper bent portion of the corrugated fin in the second heat exchange section of the midstream portion. FIG. 21 is a side sectional view illustrating a contact state between the lower surface of the top plate and the upper bent portion of the corrugated fin in the third heat exchange section in the downstream portion.

The side sectional view of FIG. 18 can be an enlarged view of a part of the cooler 1 cut along a ZX plane at the same position in the flow path width direction (Y direction) as the line A-A′ of FIG. 5, for example. The side sectional view of FIG. 19A may be a view of the portion of the cooler 1 on the right side (positive side in the X direction) with respect to the line F-F′ in FIG. 18, which is cut along the YZ plane including the line F-F′ in FIG. 18, as viewed from the negative side in the X direction. The side sectional view of FIG. 19B may be a view of the portion of the cooler 1 on the right side (positive side in the X direction) with respect to the line G-G′ in FIG. 18, which is cut along the YZ plane including the line G-G′ in FIG. 18, as viewed from the negative side in the X direction. The side sectional view of FIG. 20 may be a portion of the cooler 1 on the left side (positive side in the X direction) with respect to the line H-H′ in FIG. 18, which is cut along the ZX plane including the line H-H′ in FIG. 18, as viewed from the negative side in the X direction. The side sectional view of FIG. 21 may be a view of the portion of the cooler 1 on the right side (positive side in the X direction) with respect to the line J-J′ in FIG. 18, which is cut along the YZ plane including the line J-J′ in FIG. 18, as viewed from the negative side in the X direction. A broken line in the corrugated fin 4 of FIG. 18 indicates a surface facing the upper surface 301 side of the bottom plate portion 300 at the top portion of the upper bent portion 420. In FIGS. 19A, 19B, 20, and 21, hatching showing cross sections of the top plate 2, the plate-shaped portion 410 of the corrugated fin 4, the upper bent portion 420, and the like is omitted.

In the cooler 1 of the present embodiment, in order to make the contact area between the upper bent portion 420 of the corrugated fin 4 and the lower surface 201 of the top plate 2 increase from the upstream to the downstream, as illustrated in FIG. 18, the lower surface 201 of the top plate 2 is inclined such that the distance to the upper surface 301 of the bottom plate portion 300 (not illustrated) decreases from the upstream to the downstream. The corrugated fin 4 used in the cooler 1 according to the present embodiment can be formed such that, in all the upper bent portions 420, a height (fin length) from a lower end of the lower bent portion 430 to an upper end of the upper bent portion 420 is constant from the upstream end to the downstream end. In the cooler 1 of the present embodiment, the lower surface 201 of the top plate 2 is pressed against the upper bent portion 420 of the corrugated fin 4 in the assembly process of the cooler 1, and the upper bent portion 420 is deformed such that the contact area per unit length with the lower surface 201 of the top plate 2 as viewed in the flowing direction (X direction) of the refrigerant in each of the upper bent portions 420 increases from the upstream to the downstream. The term “contact area per unit length” refers to a contact area between the upper bent portion 420 and the lower surface 201 of the top plate 2 within a section of a unit length (for example, 1 mm) in the flowing direction of the refrigerant.

In the first heat exchange section 101A, a heat insulating region 422 in which the upper bent portion 420 illustrated in FIG. 19A is separated from the lower surface 201 of the top plate 2 and a heat contact region 421 in which a contact area per unit length between the upper bent portion 420 illustrated in FIG. 19B and the lower surface 201 of the top plate 2 is small are provided. At a position close to the upstream end in the first heat exchange section 101A, as illustrated in FIG. 19A, the thickness HO of the top plate 2 is thin, the lower surface 201 of the top plate 2 is separated from the upper bent portion 420 by a gap G6 (>0), and direct heat transfer from the top plate 2 to the corrugated fin 4 (upper bent portion 420) is blocked. On the downstream side of the position illustrated in FIG. 19A in the first heat exchange section 101A, as illustrated in FIG. 19B, the top plate 2 has a thickness H1 (>H0), and the lower surface 201 of the top plate 2 comes into contact with the upper bent portion 420. The boundary between the heat insulating region 422 and the heat contact region 421 in the first heat exchange section 101A is not limited to a specific position, but it is preferable that at least a part of the active region (for example, a region overlapping semiconductor element 501 in planar view) positioned most upstream in the first heat exchange section 101A is included in the heat contact region 421. The active region may be a region of the heating element 5 disposed in the heat exchange section 101 where the temperature overlapping the heat source in a plan view is the highest.

In the second heat exchange section 101B on the downstream side of the position illustrated in FIG. 19B in the flowing direction (X direction) of the refrigerant, as illustrated in FIG. 20, the top plate 2 has a thickness H2 (>H1), the upper bent portion 420 is deformed by the pressing load from the lower surface 201 of the top plate 2, and the contact area between the lower surface 201 of the top plate 2 and the upper bent portion 420 increases to a width W2. In the third heat exchange section 101C further on the downstream side of the position illustrated in FIG. 20 in the flowing direction (X direction) of the refrigerant, as illustrated in FIG. 21, the top plate 2 has a thickness H3 (>H2), the deformation amount of the upper bent portion 420 due to the pressing load from the lower surface 201 of the top plate 2 increases, and the contact area between the lower surface 201 of the top plate 2 and the upper bent portion 420 increases to a width W3 (>W2).

As described above, in the cooler 1 of the present embodiment, the contact area per unit length between the lower surface 201 of the top plate 2 and the upper bent portion 420 increases from the upstream to the downstream. Therefore, even if the arrangement density of the fins (plate-shaped portions 410) is the same between the upstream portion and the downstream portion, the amount of heat transfer from the top plate 2 to the upper bent portion 420 increases from the upstream to the downstream. In other words, by reducing the amount of heat transfer from the top plate 2 to the upper bent portion 420 in the first heat exchange section 101A of the upstream portion, the degree of temperature rise of the refrigerant due to heat exchange in the first heat exchange section 101A is reduced. As a result, the temperature of the refrigerant flowing into the second heat exchange section 101B in the midstream portion and the temperature of the refrigerant flowing into the third heat exchange section 101C in the downstream portion can be made relatively low, and the temperatures of the plurality of semiconductor elements 501 arranged along the flowing direction of the refrigerant can be made uniform. In the cooler 1 of the present embodiment, the inclination angle of the lower surface 201 may be changed according to the number and layout of the heating elements 5 arranged on the upper surface 200 of the top plate 2, and thus versatility of the water jacket 3 and the corrugated fin 4 is high.

The lower surface 201 of the top plate 2 in the cooler 1 of the present embodiment is not limited to the inclined surface illustrated in FIG. 18 in which the thickness of the top plate 2 continuously increases from the upstream to the downstream. The lower surface 201 of the top plate 2 may be, for example, a stepped surface whose thickness changes stepwise for each heat exchange section. In the cooler 1 of the present embodiment, the lower surface 201 of the top plate 2 may be a surface parallel to the upper surface 301 of the bottom plate portion 300, and as the corrugated fin 4 disposed in the flow path 100 of the refrigerant, a corrugated fin formed in a shape in which the height (fin length) from the lower end of the lower bent portion 430 to the upper end of the upper bent portion 420 increases from the upstream end to the downstream end may be used. In this example, the corrugated fin 4 is used which is formed such that the length of the fin is slightly shorter than the distance (flow path height) from the lower surface of the bottom plate portion 300 to the lower surface 201 of the top plate 2 at the upstream end, becomes longer than the flow path height as it goes toward the downstream end, and has a larger difference from the flow path height. After such a corrugated fin 4 is arranged on the upper surface 301 of the bottom plate portion 300 of the water jacket 3, when the top plate 2 having the lower surface 201 parallel to the upper surface 301 of the bottom plate portion 300 is attached to the water jacket 3, the contact area of each upper bent portion 420 with the top plate 2 gradually increases from the upstream to the downstream. In the cooler 1 in which the lower surface 201 of the top plate 2 and the upper surface 301 of the bottom plate portion 300 are parallel to each other, the flow path height in the flow path 100 of the refrigerant is substantially constant from the upstream to the downstream, and for example, it is possible to suppress that the cooling performance becomes non-uniform due to a difference in the flow velocity of the refrigerant between the upstream portion and the downstream portion. The upper bent portion 420 of the corrugated fin 4 and the lower surface 201 of the top plate 2 in the cooler 1 of the present embodiment may not have a section in which the upper bent portion 420 illustrated in FIG. 19A is separated from the lower surface 201, for example.

### Fifth Embodiment

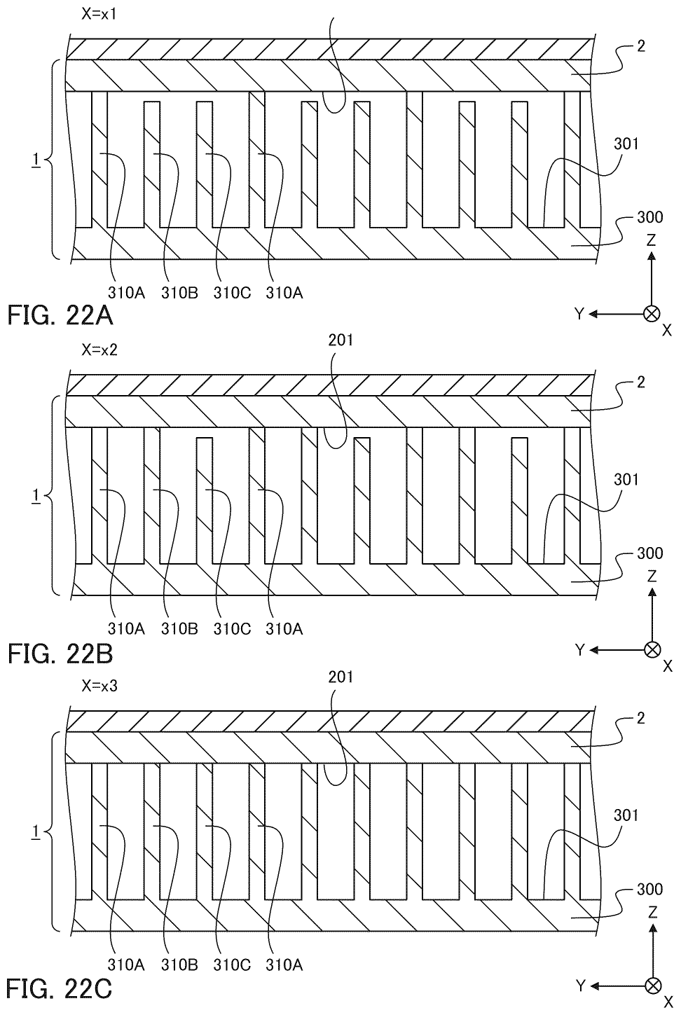

FIGS. 22A to 22C are sectional views illustrating fins of a cooler according to a fifth embodiment. The sectional view of FIG. 22A may be an enlarged view of a part of the cooler 1 cut along the YZ plane at a position x1 (refer to FIG. 2) in the first heat exchange section 101A of the upstream portion. The sectional view of FIG. 22B may be an enlarged view of a part of the cooler 1 cut along the YZ plane at a position x2 (refer to FIG. 2) in the second heat exchange section 101B of the midstream portion. The sectional view of FIG. 22C may be an enlarged view of a part of the cooler 1 cut along the YZ plane at a position x3 (refer to FIG. 2) in the third heat exchange section 101C of the downstream portion.

In the cooler 1 of the present embodiment, as illustrated in FIGS. 22A to 22C, a plurality of plate-shaped fins 310 arranged in a flow path width direction (Y direction) in flow path 100 of the refrigerant are integrally formed with bottom plate portion 300. The plate-shaped fin 310 may include the plate-shaped portion 410 and the upper bent portion 420 of the corrugated fin 4 exemplified in the first to fourth embodiments, and each of the plate-shaped fins 310 is disposed in parallel with the flowing direction (X direction) of the refrigerant. The water jacket 3 integrally formed with the plate-shaped fins 310 can be manufactured by, for example, casting, a method using a 3D printer, or the like. Note that a plate-shaped fin member in which the plate-shaped fin 310 is coupled to another bottom plate may be disposed on the bottom plate portion 300.

A first plate-shaped fin 310A in the first contact state is a heat contact region in which the tip of the fin is in contact with the lower surface 201 of the top plate 2 in the entire region from the upstream end to the downstream end in the flowing direction (X direction) of the refrigerant. Therefore, the heat exchange between the first plate-shaped fin 310A and the refrigerant is performed in all the sections of the first heat exchange section 101A, the second heat exchange section 101B, and the third heat exchange section 101C.

In a second plate-shaped fin 310B in the second contact state, a portion from the upstream end in the flowing direction of the refrigerant to the position x4 (refer to FIG. 2) between the first heat exchange section 101A and the second heat exchange section 101B is set as the heat insulating region, and a portion from the position x4 to the downstream end is set as the heat contact region. In addition, a third plate-shaped fin 310C in the third contact state, a portion from the upstream end in the flowing direction of the refrigerant to the position x5 (refer to FIG. 2) between the second heat exchange section 101B and the third heat exchange section 101C is set as the heat insulating region, and a portion from the position x5 to the downstream end is set as the heat contact region. For example, each of the second plate-shaped fin 310B and the third plate-shaped fin 310C may have a shape (refer to the first embodiment) in which the upper surface of the section serving as the heat insulating region is inclined such that the distance from the lower surface 201 of the top plate 2 increases toward the upstream end, or may have a shape (refer to the third embodiment) in which the length of the fin is changed stepwise at the boundary between the heat insulating region and the heat contact region. In the first heat exchange section 101A, the heat exchange between the second plate-shaped fin 310B and the refrigerant and the heat exchange between the third plate-shaped fin 310C and the refrigerant are not substantially performed. Therefore, the refrigerant flowing along the heat exchange surface of the second plate-shaped fin 310B and the refrigerant flowing along the heat exchange surface of the third plate-shaped fin 310C in the first heat exchange section 101A flow to the second heat exchange section 101B while having a lower temperature than the refrigerant flowing along the heat exchange surface of the first plate-shaped fin 310A.

In the second heat exchange section 101B, the heat exchange between the first plate-shaped fin 310A and the refrigerant and heat exchange between the second plate-shaped fin 310B and the refrigerant are performed. At this time, since the temperature of the refrigerant flowing along the heat exchange surface of the second plate-shaped fin 310B is lower than the temperature of the refrigerant flowing along the heat exchange surface of the first plate-shaped fin 310A, as described above, the temperature difference between the temperature of the heating element 5 in the first heat exchange section 101A and the temperature of the heating element 5 in the second heat exchange section 101B can be reduced. Similarly, in the third heat exchange section 101C, the heat exchange between the refrigerant having a relatively low temperature flowing along the heat exchange surface of the third plate-shaped fin 310C and the third plate-shaped fin 310 is added, so that the temperature difference between the temperature of the heating element 5 in the second heat exchange section 101B and the temperature of the heating element 5 in the third heat exchange section 101C can be reduced.

Note that, in the cooler 1 of the present embodiment, dimensions (lengths of fins) in the flow path height direction (Z direction) of all plate-shaped fins 310 are constant, and the grooves 202 may be formed at positions corresponding to the heat insulating regions of the second plate-shaped fins 310B and the third plate-shaped fins 310C on the lower surface 201 of the top plate 2 (refer to the second embodiment). Further, as described in the fourth embodiment, by inclining the lower surface 201 of the top plate 2 or increasing the length of the plate-shaped fin 310 from upstream to downstream, the contact area per unit length in the flowing direction (X direction) of the refrigerant may be increased from the upstream to the downstream. The shape of the plate-shaped fin 310 in the cooler 1 according to the present embodiment is not limited to the flat shape of the heat exchange surface, and may be a shape having irregularities that generate turbulence in the refrigerant flowing along the heat exchange surface.

Further, in the cooler 1 of the present embodiment, a plurality of pin-shaped fins may be arranged in the flow paths 100 of the refrigerant instead of the plate-shaped fins 310. When the plurality of pin-shaped fins are arranged, for example, a set of pin-shaped fins arranged in the flowing direction (X direction) of the refrigerant is regarded as the plate-shaped fins 310, and the number of pin-shaped fins in contact with the lower surface 201 of the top plate 2 is adjusted for each set of pin-shaped fins, whereby the contact area between the pin-shaped fins and the top plate 2 at each position in the flowing direction of the refrigerant can be increased from the upstream to the downstream without changing the arrangement density of the pin-shaped fins between the upstream portion and the downstream portion.

The cooler 1 according to the above-described embodiment is merely an example of the cooler 1 according to the present invention. The number of the heating elements 5 arranged on the top plate 2 of the cooler 1, the configuration of the heating elements 5, and the like are not limited to those described above. The boundary between the heat insulating region 422 and the heat contact region 421 may be, for example, between the semiconductor elements 501 adjacent to each other in the flowing direction of the refrigerant in one heat exchange section 101 (heating element 5). Specifically, in addition to the above-described three contact states, the corrugated fin 4 in the cooler 1 illustrated in FIGS. 1 and 2 may have a shape having one or more contact states among a contact state in which the boundary between the heat insulating region 422 and the heat contact region 421 is at the position x1, a contact state in which the boundary between the heat insulating region 422 and the heat contact region 421 is at the position x2, and a contact state in which the boundary between the heat insulating region 422 and the heat contact region 421 is at the position x3. The inlet 110 of the refrigerant and the outlet 111 of the refrigerant in the cooler 1 may be formed in, for example, the bottom plate portion 300 or the top plate 2. Furthermore, the inlet 110 of the refrigerant and the outlet 111 of the refrigerant may be formed at ends of the frame portion 320 in the lateral direction.

The application of the cooler 1 according to the above-described embodiment is not limited to a specific application, but is particularly suitable for cooling a semiconductor module operating in a high-temperature environment. For example, the semiconductor module provided with the cooler 1 can also be applied to a power conversion device such as an inverter device that drives a motor of a vehicle such as a four-wheeled automobile, a two-wheeled vehicle, or a railway vehicle. The semiconductor module provided with the cooler 1 of the above-described embodiment may be applied to, for example, an industrial power conversion apparatus such as an inverter device that drives a motor of an elevator, an escalator, or an air conditioning system of a building. The semiconductor module is not limited to the inverter device, and may provide other functions.

The embodiments of the cooler and the semiconductor module according to the present invention are not limited to the above embodiments, and may be variously modified, replaced, and deformed without departing from the spirit of the technical idea. Further, when the technical idea may be implemented in another method by the progress of the technology or another derived technology, the technical idea may be carried out by using the method thereof. Hence, the claims cover all embodiments that may be included within the scope of the technical idea. Hereinafter, feature points in the above-described embodiments will be summarized.

A cooler according to the above-described embodiment includes a top plate portion having a first surface facing a flow path of a refrigerant and having a heating element disposed on a back surface of the first surface; a bottom plate portion having a second surface facing the first surface of the top plate portion; a plurality of fins arranged between the first surface of the top plate portion and the second surface of the bottom plate portion; and a frame portion provided between the top plate portion and the bottom plate portion and having a wall surface surrounding the plurality of fins, in which the plurality of fins are arranged between the first face of the top plate portion and the second surface of the bottom plate portion such that an arrangement density of fins in a first section of the flow path of the refrigerant is equal to an arrangement density of fins in a second section downstream of the first section, and a contact area between the fin and the top plate portion in the first section is smaller than a contact area between the fin and the top plate portion in the second section.

In the cooler according to the above embodiment, the plurality of fins include a plurality of plate-shaped portions arranged side by side in a direction orthogonal to a flowing direction of the refrigerant in the flow path of the refrigerant, in the plurality of plate-shaped portions, each plate-shaped portion extends in a flowing direction of the refrigerant, and some plate-shaped portions among the plurality of plate-shaped portions are separated from the first surface of the top plate portion in the first section on an inlet side with respect to a predetermined position between an upstream end on the inlet side of the refrigerant and a downstream end on an outlet side of the flow path of the refrigerant, and are connected to the first surface of the top plate portion in the second section on the downstream side of the predetermined position.

In the cooler according to the above embodiment, the plurality of plate-shaped portions include a first plate-shaped portion in which an entire region from the upstream end to the downstream end is connected to the first surface of the top plate portion, and a second plate-shaped portion separated from the first surface of the top plate portion in the first section.

In the cooler according to the above embodiment, the second plate-shaped portion includes a plurality of plate-shaped portions having different lengths of regions separated from the first surface of the top plate portion in the flowing direction of the refrigerant.

In the cooler according to the above embodiment, the plurality of fins are a plurality of plate-shaped portions in a corrugated fin formed by bending a plate-shaped heat conduction member into a wave shape, and the contact area between the fin and the top plate portion is a contact area between a bent portion connecting adjacent plate-shaped portions and the top plate portion.

In the cooler according to the above embodiment, the bent portion in contact with the top plate portion includes a first bent portion in contact with the top plate portion in the first section, and a second bent portion separated from the top plate portion in the first section.

In the cooler according to the above embodiment, the second bent portion has a distance from the first surface of the top plate portion increasing toward an upstream side in the first section.

In the cooler according to the above embodiment, the second bent portion has a step between a portion in the first section and a portion in the second section.

In the cooler according to the above embodiment, in the second bent portion, a portion in the second section has a curved surface shape protruding toward the first surface of the top plate portion, and a portion in the first section is a flat surface separated from the first surface of the top plate portion.

In the cooler according to the above embodiment, the second bent portion has the same height from the second surface of the bottom plate portion from an upstream end to a downstream end, and a groove that separates the top plate from the second bent portion in the first section is formed on the first surface of the top plate.

In the cooler according to the above embodiment, a contact area of the bent portion with the first surface of the top plate portion per unit length as viewed in a flowing direction of the refrigerant increases from upstream to downstream.

In the cooler according to the above embodiment, a flowing direction of the refrigerant is a longitudinal direction of a flow path of the refrigerant in a plan view of the first surface of the top plate.

A semiconductor module according to the above-described embodiment includes the cooler according to the above-described embodiment; a heating element disposed on a back surface of the first surface of the top plate of the cooler, in which the heating element includes a wiring board and a semiconductor element.

As described above, the present invention has an effect that the temperature of the heating element along the flowing direction of the refrigerant of the cooler applied to the semiconductor module and the like can be made uniform, and in particular, it is useful to apply the present invention to a semiconductor module having a high calorific value at the time of operation, such as for industrial use or for electrical equipment.

What is claimed is:

1. A cooler having a flow path for a refrigerant, the flow path including a first section and a second section downstream to the first section, the cooler comprising:
a top plate, having
a first surface facing the flow path of the refrigerant, and
a second surface opposite to the first surface, and being configured to have a heating element disposed thereon;
a bottom plate having a first surface and a second surface opposite to each other, the second surface of the bottom plate facing the first surface of the top plate;
a plurality of fins arranged between the first surface of the top plate and the second surface of the bottom plate; and
a frame provided between the top plate and the bottom plate, and having a wall surface surrounding the plurality of fins, wherein
the plurality of fins are so arranged that an arrangement density thereof in the first section is equal to an arrangement density thereof in the second section, and
a contact area between the plurality of fins and the top plate in the first section is smaller than a contact area between the plurality of fins and the top plate in the second section.

2. The cooler according to claim 1, wherein
the plurality of fins include a plurality of plate-shaped portions arranged side by side in a direction orthogonal to a flowing direction of the refrigerant in the flow path,
each of the plurality of plate-shaped portions extends in a flowing direction of the refrigerant,
at least one of the plurality of plate-shaped portions is separated from the first surface of the top plate in the first section upstream to a predetermined position, and
at least another one of the plurality of plate-shaped portions is connected to the first surface of the top plate in the second section downstream of the predetermined position.

3. The cooler according to claim 2, wherein the plurality of plate-shaped portions include:
a first plate-shaped portion that is connected in its entirety with respect to the flowing direction of the refrigerant to the first surface of the top plate, and
a second plate-shaped portion that has at least a portion thereof separated from the first surface of the top plate in the first section.

4. The cooler according to claim 3, wherein the plurality of plate-shaped portions further include another second plate-shaped portion that has at least a portion thereof separated from the first surface of the top plate, a length of the portion of the second plate-shaped portion and a length of the portion of the another second plate-shaped portion being different in the flowing direction of the refrigerant.

5. The cooler according to claim 1, wherein
the plurality of fins are formed by bending a plate-shaped heat conduction member into a wave shape, to thereby include a plurality of plate-shaped portions, each adjacent two of which are connected by a bent portion, and
the contact area between the plurality of fins and the top plate is a contact area between the plurality of bent portions and the top plate.

6. The cooler according to claim 5, wherein the plurality of bent portions includes:
a first bent portion in contact with the top plate in the first section, and
a second bent portion separated from the top plate in the first section.

7. The cooler according to claim 6, wherein a distance between the second bent portion and the first surface of the top plate increases toward an upstream side in the first section.

8. The cooler according to claim 6, wherein the second bent portion has a step, which is located between a portion in the first section and a portion in the second section.

9. The cooler according to claim 8, wherein in the second bent portion,
the second section includes a portion that has a curved surface protruding toward the first surface of the top plate, and
the first section includes a portion that has a flat surface separated from the first surface of the top plate.

10. The cooler according to claim 6, wherein
the second bent portion has a same height from the second surface of the bottom plate from an upstream end to a downstream end thereof, and
a groove that separates the top plate from the second bent portion in the first section is formed on the first surface of the top plate.

11. The cooler according to claim 5, wherein a contact area per unit length of the bent portions with the first surface of the top plate increases from upstream to downstream.

12. The cooler according to claim 1, wherein the refrigerant flows in a flowing direction which is a longitudinal direction of the flow path of the refrigerant in a plan view of the cooler.

13. A semiconductor module comprising:
the cooler according to claim 1; and
a heating element disposed on the second surface of the top plate of the cooler,
wherein the heating element includes a wiring board and a semiconductor element.
